(19) United States
(12) Patent Application Publication
(10) Pub. No.: US 2026/0352228 A1
(43) Pub. Date: Nov. 5, 2026

(54) FAST COMPRESSION BY SELECTING THE POSITIONS FOR COMPARISONS IN COMPRESSION ACCELERATORS

(71) Applicant: Intel Products IP LLC, Santa Clara, CA (US)

(72) Inventors: James GUILFORD, Northborough, MA (US); Vinodh GOPAL, Westborough, MA (US); Daniel F. CUTTER, Maynard, MA (US)

(21) Appl. No.: 19/685,412

(22) Filed: May 22, 2026

(51) Int. Cl. H03M 7/30; G06F 7/02; G06F 7/24

(52) U.S. Cl. CPC H03M 7/3084; G06F 7/02; G06F 7/24; H03M 7/3077; H03M 7/6011

(57) ABSTRACT

Methods and apparatus for fast compression by selecting the positions for comparisons in compression accelerators. For a sequence of N positions in a lookahead buffer, M out of the N positions are selected for which compare operations are to be performed, where M<N. In one aspect, selection of the M out of the N positions utilizes a permutation order comprising a permutation of an original order of the sequence of N positions. In another aspect, hash collisions are considered in combination with the permutation order where for any positions that would result in a hash table collision, the first of the positions in the permutation order is selected with the other colliding position(s) skipped. The compare results are performed by M compare pipelines in parallel to generate compare results identifying positions of longest matches in a history buffer including search strings beginning at the M positions in the lookahead buffer.

### BACKGROUND INFORMATION

Compression is compute-intensive and benefits significantly from specialized hardware accelerators. LZ77 compressors, such as the popular Deflate algorithm, find matches between the current bytes and a previous occurrence in the input stream within a history window. If a match is not found, the data is represented as literals. Data is compressed as a result of finding matches since a match can be encoded compactly with a <length, relative backward-distance offset> pair, rather than all the literal bytes that it represents.

Better/longer matches result in better compression. Finding the best match with traditional approaches is a very expensive operation in terms of time and hardware cost, because this usually requires finding a large number of matches and then selecting the best one. Choosing the best match at a given position without considering the matches at subsequent positions, will provide results that can be improved.

### BRIEF DESCRIPTION OF THE DRAWINGS

The foregoing aspects and many of the attendant advantages of this disclosure will become more readily appreciated as the same becomes better understood by reference to the following detailed description, when taken in conjunction with the accompanying drawings, wherein like reference numerals refer to like parts throughout the various views unless otherwise specified:

FIG. 1 is a schematic diagram illustrating a sliding window-based string match search scheme;

FIG. 2 is a graph depicted a distribution of matched string lengths vs. percentage of occurrences;

FIG. 3 is a flowchart illustrating operations and logic employed by a conventional LZ77 encoder;

FIG. 4 is a diagram illustrating encoding a character string using conventional LZ77 encoding;

FIG. 5 is a diagram illustrating an apparatus including one or more compare units and a match sharer, according to one embodiment;

FIG. 5a shows exemplary inputs provided to the match sharer of the apparatus of FIG. 5;

FIG. 5b shows exemplary best matches being output to downstream logic and an exemplary compressed output, according to one embodiment;

FIG. 6 is a flowchart illustrating operations performed using the apparatus of FIG. 5, according to one embodiment;

FIG. 7a is a flowchart illustrating operations performed using one or more compare units, according to one embodiment;

FIG. 7b is a flowchart illustrating operations performed with the match sharer, according to one embodiment;

FIGS. 8a and 8b collectively show processing of a portion of a byte stream to identify compare results using forward and backward compare operations, according to one embodiment;

FIG. 8c shows forward and backward character matching for a current position of 100 and a forward match location of 750;

FIG. 8d shows forward and backward character matching for a current position of 100 and a forward match location of 312;

FIG. 8e shows forward and backward character matching for a current position of 101 and a forward match location of 751;

FIG. 8f shows forward and backward character matching for a current position of 102 and a forward match location of 857;

FIG. 8g shows forward and backward character matching for a current position of 103 and a forward match location of 777;

FIG. 9 is a diagram illustrating an implementation employing 4 parallel pipelines that processes 8 positions per cycle, with 4 positions being skipped, according to one embodiment;

FIG. 9a is a diagram illustrating an alternate implementation of the embodiment of FIG. 9 that does not include a match sharer;

FIG. 10 is a diagram illustrating an implementation of a hash table in memory including 16 banks with respective ports, according to one embodiment;

FIG. 11 is a flowchart illustrating operations and logic for implementing a scheme combining use of permutations with consideration of hash collisions, according to one embodiment;

FIG. 12 is a table comparing computed average of compression ratios using different permutation orders and datasets;

FIG. 13 is schematic diagram illustrating an exemplary implementation system including a cloud-hosted service the serves various clients via the Internet and under which embodiments of the match sharing scheme in hardware compression accelerators may be implemented;

FIG. 14a is a frontal isometric view of an exemplary blade server chassis in which a plurality of server blades are installed;

FIG. 14b is a rear isometric view of the blade server chassis of FIG. 14a;

FIG. 14c is an isometric frontal view of an exemplary blade server rack in which a plurality of rack-mounted blade server chassis corresponding to FIGS. 16a and 16b are installed; and

FIG. 15 shows details of the components of a typical server blade, according to one embodiment;

FIG. 16 is a diagram illustrating generalized platform hardware implemented in various types of clients shown in FIG. 19; and

FIG. 17 is a schematic diagram of a platform architecture including a processor having an on-chip accelerator configured to implement parity-encoded compression and decompression operations in accordance with one or more embodiments disclosed herein.

### DETAILED DESCRIPTION

Embodiments of methods and apparatus for fast compression by selecting the positions for comparisons in compression accelerators are described herein. In the following description, numerous specific details are set forth to provide a thorough understanding of embodiments disclosed herein. One skilled in the relevant art will recognize, however, that the embodiments can be practiced without one or more of the specific details, or with other methods, components, materials, etc. In other instances, well-known structures, materials, or operations are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

### LZ77 Compression and Decompression

LZ77 compression schemes find repeated substrings and replace them with backward references (relative distance offsets in the original stream). The compressed data comprises of a series of elements of two types: literal bytes and pointers to replicated strings, where a pointer is represented as a pair <length, backward distance offset in the uncompressed stream>. Entropy encoding (e.g. Huffman coding) utilizes variable length codes to represent symbols such that frequent symbols get short codes and infrequent symbols get long codes, thereby representing the set of symbols compactly.

The DEFLATE scheme uses a combination of LZ77 compression and Huffman encoding (entropy encoding) to encode a bitstream comprising a sequence of blocks. A block is preceded by a 3-bit header that identifies whether or not the block is the last block in the stream and the type of encoding method used for the block. Many or most blocks will end being encoded using dynamic Huffman encoding, while other blocks may store a literal or string between 0 and 65,535 bytes in length. Static Huffman encoding may also be used for some blocks.

Compression is achieved through two operations. The first operation comprises string matching and replacement of duplicate strings with pointers. The second operation comprises replacing symbols with new, weighted symbols based on frequency of use. Within compressed blocks, if a duplicate series of bytes (a repeated string) is detected, then a back-reference is inserted (referred to herein as a reference), linking to the previous location of that identical string instead. An encoded match to an earlier string consists of a length L (or Len) (3-258 bytes) and a distance D (1-32,768 bytes (32 KB)). Relative back-references can be made across any number of blocks, as long as the distance appears within the last 32 KB of uncompressed data decoded, which is referred to as the sliding window. Under another variant, a 64 KB window is used.

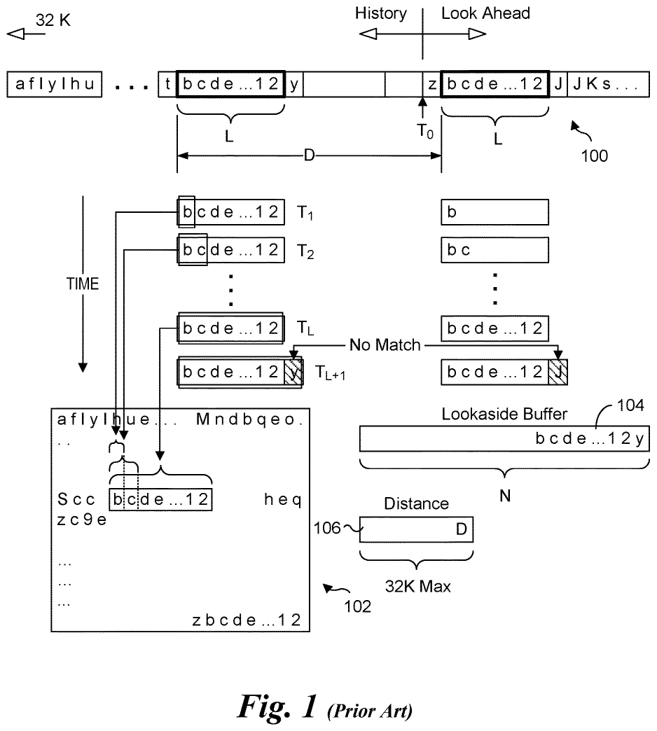

FIG. 1 illustrates an example of a finding a match of length L in accordance with a sliding window match scheme. As bytes in a byte stream 100 are received, a match detection scheme employing a sliding window is employed to determine whether there is an identical byte pattern that has been previously received and processed. The process stage shown in FIG. 1 corresponds to a state at which a prior portion of byte stream 100 has been received and processed, as illustrated by the History arrow and data in a history buffer 102 in which the sliding window portion of the byte stream is temporally stored. Accordingly, once the history buffer 102 is filled to the 32 KB limit, the content of history buffer 102 incrementally changes with each cycle, removing the oldest character and adding the last character in byte stream 100 that was processed. For illustrative purposes, byte stream 100 is depicted as a stream of alphanumeric characters, rather than individual bits, which would be how the data would be encoded in an actual byte stream. Also, for illustrative purposes, it is presumed that the alphanumeric characters are encoded as ASCII characters, such that each character is represented by 8 bits, or a single byte, thus the terminology “byte stream.” Other 8-bit encodings could also be employed.

The arrow depicting time To corresponds to the start of a processing cycle in which a byte corresponding to a character ‘z’ is evaluated for a match. From a conceptual view, a pattern match operation is performed evaluating character ‘z’ against previously received characters (bitmap patterns) in byte stream 100. In the case of DEFLATE, the size of the history buffer is limited up to the previous 32K bytes of bitstream content. To evaluate the ‘z’ for a match, history buffer 102 will be searched for a match (which in this case would be a single individual character ‘z’ that may have been previously received). In this particular example, a prior character ‘z’ has not been received such that there is no match. According, a literal ‘z’ will be forwarded for further processing, such as to an entropy coder.

Next, at a time T₁, a character ‘b’ is encountered. At time T₁ a search for character ‘b’ is commenced.” In this case a prior ‘b’ has been received (within the 32 KB sliding window), and thus there is a match. In response to a match, further searching will be performed by adding one additional character (in byte stream 100) at a time to create incrementally longer search strings with evaluation continuing until a string match is not found. During a processing cycle beginning at time T₂, a second character ‘c’ is added to ‘b’ to create a search string ‘b c’, which is searched for in history buffer 102. In one embodiment, a hashing scheme is implemented to facilitate string match searching, such as the hashing scheme defined for DEFLATE in RFC 1951. As before, a match is found, and the process is repeated again multiple times until we reach a cycle corresponding to time T_{L}. At this point, the search string ‘b c d e . . . 1 2’ is searched for a match. Since this same string has been previously retrieved, a match is found.

In conjunction with the foregoing string search evaluation sequence, for every added character to the string search window the corresponding character is added to a look-aside buffer 104 such that the string in the look-aside buffer at a given point in time matches the current search string window. Also, for each match result, data in a distance register 106 is updated to indicating the distance in bytes to the nearest match.

At a time T_{L+1} a character ‘J’ is encountered, such that the match string is now ‘b c d e . . . 1 2 J’. Meanwhile the next character in the prior match string is ‘y’ (and it is presumed that no other strings ‘b c d e . . . 1 2 J’ where previously received within the 32K sliding window. As a result, there is a miss. At this point, data indicating the length of the longest matched string in look-aside buffer 104 corresponding to the prior match (which can be obtained by removing the last added character) and data in the distance register 106 identifying the distance to the matched string is encoded as a token comprising a <len, distance> pair.

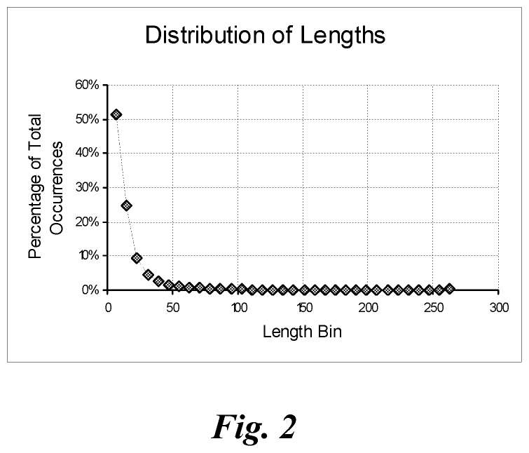

Under DEFLATE there can be a matching string length of up to 258 bytes. Under a conventional approach, a hardware look-aside buffer of at least 258 bytes would be used to ensure that any match of 258 bytes or less (that is, any legal DEFLATE string match) could be buffered. However, the frequency of encountering a string match of 258 bytes or more is extremely small. Moreover, the frequency of finding string matches based on length can be approximated as an inverse exponential equation under which the frequency falls off rapidly as the bit length increases. For example, the graph 200 in FIG. 2 is illustrative of the distribution of matching lengths as a percentage of occurrences one might find for a large corpus of files obtained, for example, from the top 500 web sites.

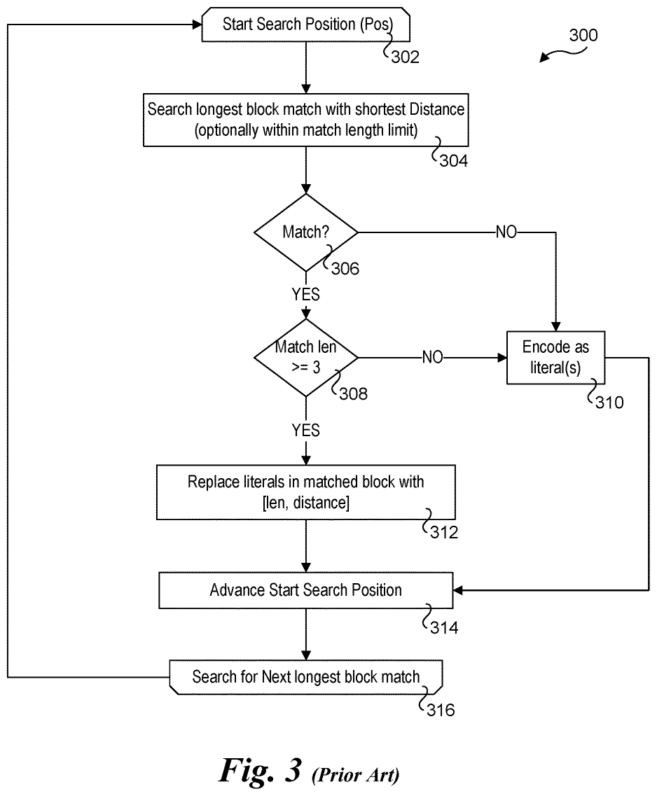

FIG. 3 shows a flowchart 300 illustrating operations and logic performed by a conventional implementation of the LZ77 compression scheme. As shown by start and end loop blocks 302 and 316, the operations are performed in a loop-wise manner until processing of the file (or whatever content is being encoded) is complete.

The loop begins with start loop block 302, which corresponds to the start of the search position (the position at which the next search process begins, referred to herein as ‘Pos’). In a block 304 a search for the longest block match with shortest distance is performed, optionally including a match length limit (e.g., the length of the longest match is limited). Details of this process are described above with reference to FIG. 1 and are well known. As depicted by decision block 306 and 308, if there is no match or if the longest match has a length that is less than 3, the logic proceeds to a block 310 in which the byte values are encoded as literals, and then to a block 314 where the start search position Pos is advanced by the number of literals that are encoded. The logic then proceeds to end loop block 316, which returns the processing to start loop block 302 to begin searching for the next longest match block in block 304.

If the result of the longest block match returns a block with a length of greater or equal to 3, the answer to decision block 308 will be YES, and the logic will proceed to replace the literals in the matched block with [len, distance], where len is the length of the match block and distance is the shortest distance to a previous block that is matched. As before, the start search position is advanced in block 314 (this time by len), and the logic loops back from end loop block 316 to start loop block to repeat the process.

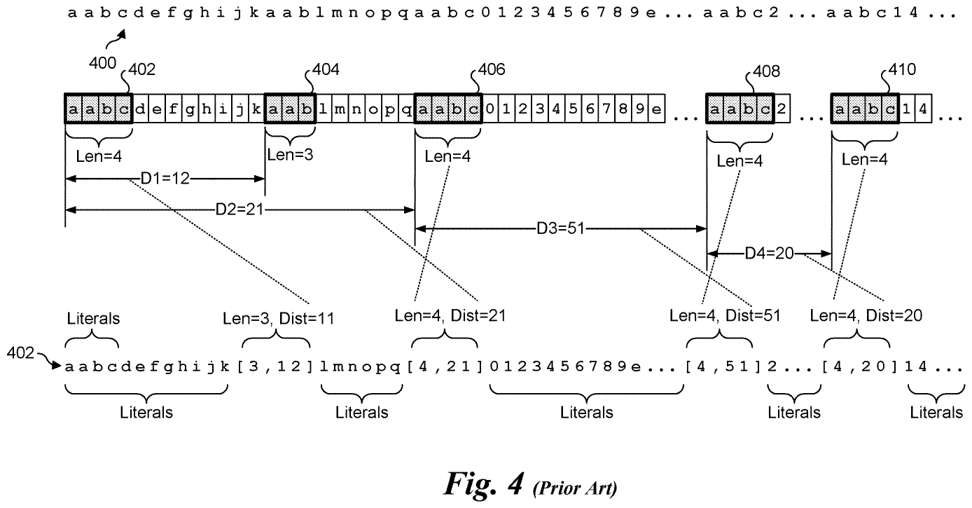

FIG. 4 depicts how a character string in a byte stream 400 is encoded into an encoded stream 402 using a conventional implementation of the LZ77 compression scheme using the operations and logic of flowchart 300. For illustrative purposes, the byte streams herein are shown using character strings rather than the actual byte values used by ASCII. As illustrated, the character string includes an ‘a a b c’ block 402, an ‘a a b’ block 404, an ‘a a b c’ block 408, and an ‘a a b c’ block 410 interspersed with various other alphanumeric characters. Since LZ77 encodes and decodes from a sliding window over previously seen characters, decompression must always start at the beginning of the input, which begins with ‘a’, ‘b’, ‘c’, ‘d’, ‘e’, etc. for byte stream 400. In this example implementation, the minimum matching length (‘len’) is 3, the same as used in DEFLATE.

Using the sliding window comparison scheme described above with reference to FIG. 1, no matches with a length of at least 3 would be detected until ‘a a b’ block 404 is reached, which matches the first three characters of ‘a a b c’ block 402. In accordance with decision block 306 and block 310 of flowchart 300, up until the position and the start of ‘a a b’ block 404, byte stream 400 would be encoded as literals ‘a’, ‘a’, ‘b’, ‘c’, ‘d’, ‘e’, ‘f’, ‘g’, ‘h’, ‘i’, ‘j’, ‘k’ in encoded stream 402. Since the match of ‘a a b’ block 304 has a length of 3, the ASCII byte values for literals ‘a’, ‘a’, ‘b’ would be encoded as [3,12], representing a length of 3 at a distance of 12 from the matching ‘a a b’ substring in ‘a a b c’ block 302. Similarly, after a sequence of literals ‘1’, ‘m’, ‘n’, ‘o’, ‘p’, ‘q’, block ‘a a b c’ 306 would be encoded as [4, 21], followed by literals ‘0’, ‘1’, ‘2’, ‘3’, ‘4’, ‘5’, ‘6,’ ‘7’, ‘8’, ‘9’, ‘e’, . . . , [4, 51] for block ‘a a b c’ 308, literals ‘2’, . . . , [4, 20] for block ‘a a b c’ 310, and literals ‘1’, ‘4’ . . . .

The process of decompressing DEFLATE streams is effectively the inverse of compressing DEFLATE streams and has two phases:
1. Decoding the input stream into tokens (literals or references to repeated strings)
2. Copying either the literal bytes or repeated strings (with specified length/offset) to the output stream (LZ77 back-end output generation)

To achieve high levels of compression (e.g., max level 9 in DEFLATE/zlib), 100's of locations may need to be examined, which are typically provided by an underlying hash table and lists structures. The embodiments described and illustrated herein provide a solution that finds high quality matches quickly without requiring a wide hash table or costly multi-ported/replicated history buffer memories.

In accordance with some aspects of the embodiments disclosed herein, a match sharing scheme is implemented for compression of data (e.g., byte streams). In some exemplary embodiments illustrated herein, the match sharing scheme is implemented for compression using a modified DEFLATE scheme. However, this is not meant to be limiting, as the technique can generally be applied to other compression schemes in a similar manner, such as but not limited to LZ4 and ZStandard.

In some embodiments, a mechanism to search for the best matches uses a small flat hash table with a small number of entries. For instance, in one embodiment a table with 1024 entries with each entry containing 4 locations of potential matches. Let the offset in the data stream that is currently being compressed be called the “position”. Let the offsets in the hash table entries be called “pointers”, as they point into the history buffer to indicate locations that may contain matches.

A “compare unit” takes the data at the current position and a pointer into the history buffer, compares the current data against the data pointed to by the pointer, and finds the size of the match. Depending on the mode, there may be one compare for a given position, or a small number (e.g., 4) compares for a given position.

Under the embodiments, the compare operations search forwards and backwards when comparing the data from the current position and from the history buffer. Also, the results for the current position are “shared” with adjacent positions to see if the match from one position results in a better match for another position.

This approach reduces the need for large hash tables, large multi-ported history buffer memories, and massive parallel compare units, thereby enabling very efficient hardware implementations. It achieves the compression ratio of traditional high-level (maximal ratio) compressors, with the cost and speed of low-level (high speed, low ratio) compressors.

The hash table contains pointers to locations that start with the same short (typically 3) byte sequence, or at least two sequences that hash to the same value. The hash table entry contains the closest set of such pointers. This is beneficial as it takes fewer bits to encode shorter distances.

For example, consider the case where the current position was 1000. The data starting at position 1000 is ‘A B C D E F G H’. Assume that the sequence ‘A B C’ was a very common sequence. Then the hash table entry for ‘A B C’ might contain pointers 990, 970, 950, 920. In this example, assume that each of these locations contain ‘A B C’ followed by random bytes. Then the best compare match for 1000 would be a 3-byte match at location 990, the closest one.

If there was a longer match, e.g., ‘A B C D E F G’ located at position 800, this would be missed by the compare unit, because the pointer to 800 was flushed out of the hash table entry by the more numerous and closer ‘A B C’ sequences. However, if ‘D E F’ is not a commonly occurring sequence, then there would likely be a pointer to 803 in the hash table entry for ‘D E F.’ When the compare unit was processing position 1003, it would find a 4-byte match at location 803 (matching ‘D E F G’). But it would also find that the match extended backwards by 3 bytes. This means that the match at position 1003 actually implies a number of matches, as shown in TABLE 1.

TABLE 1

| Position | Pointer | Length |
|---|---|---|
| 1003 | 803 | 4 |
| 1002 | 802 | 5 |
| 1001 | 801 | 6 |
| 1000 | 800 | 7 |

When the results from the compare unit for position 1003 are “shared” with location 1000, the results are better, and position 1000 can then send the better match (length of 7 at offset 800) to the downstream logic.

To implement this, there is a “match sharer” unit. In one embodiment, this is essentially a pipeline of the previous N (e.g., 24) positions. For example, if the current position was 1024, then it would contain the best match for positions 1023, 1022, . . . , 1000. The best match(s) from position 1024 would be broadcast to each entry in the match sharer, and each such entry would be updated if the new match was applicable to the given position, and it was a better match than the current one.

Then the last entry (e.g., 1000) would be shifted out and sent to the downstream logic, and the latest match shifted in. After this, the match sharer would contain entries for positions 1024, 1023, . . . , 1001.

With a hash table that only provides 4 locations to search per position (and only 4 compare units), in the best-case scenario (assuming long match lengths that apply to all neighboring entries), we almost get the effect of picking the best match from 4*24 candidates without doing those many computations at the current position.

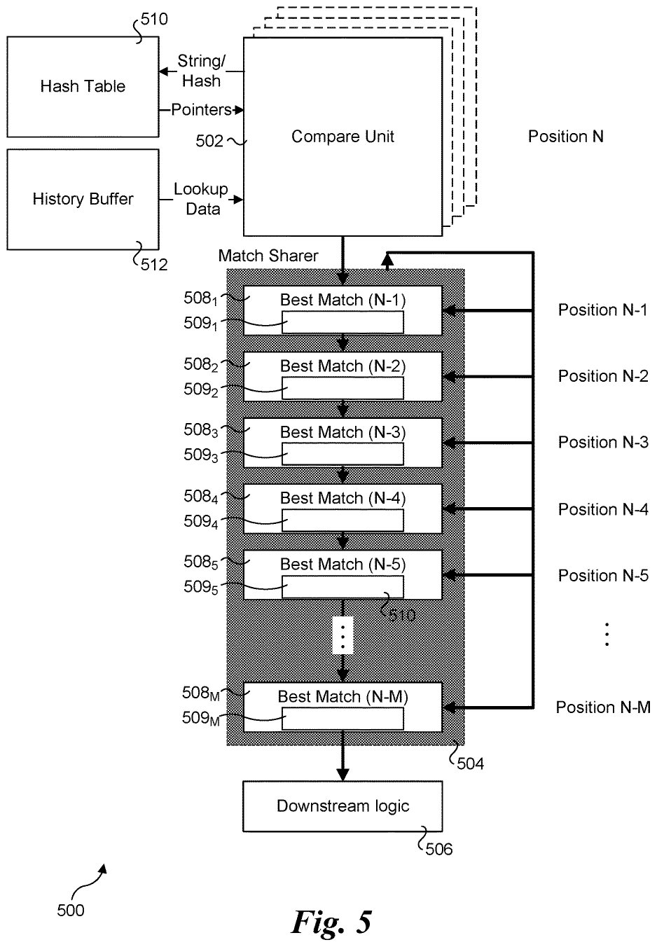

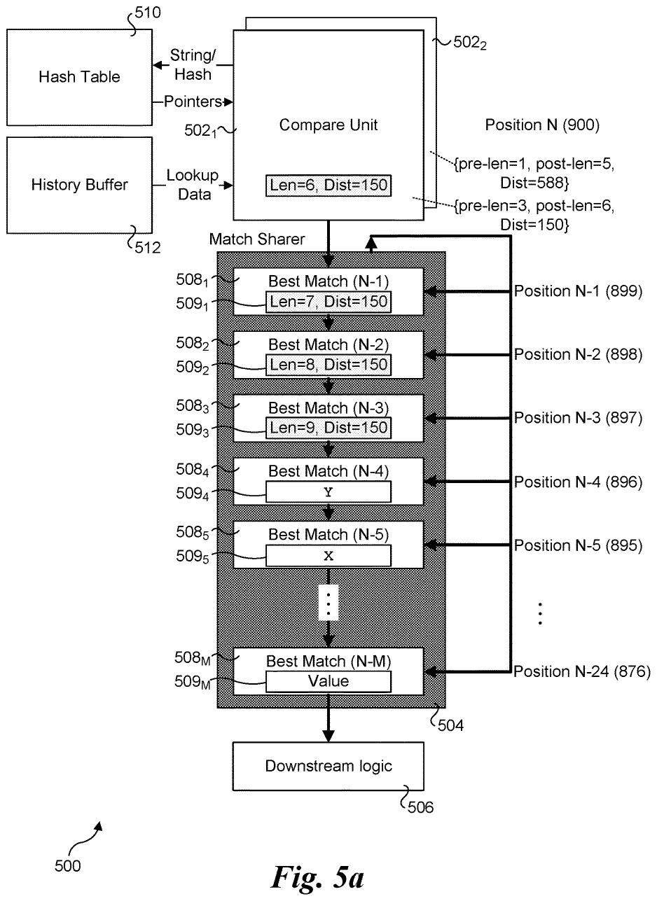

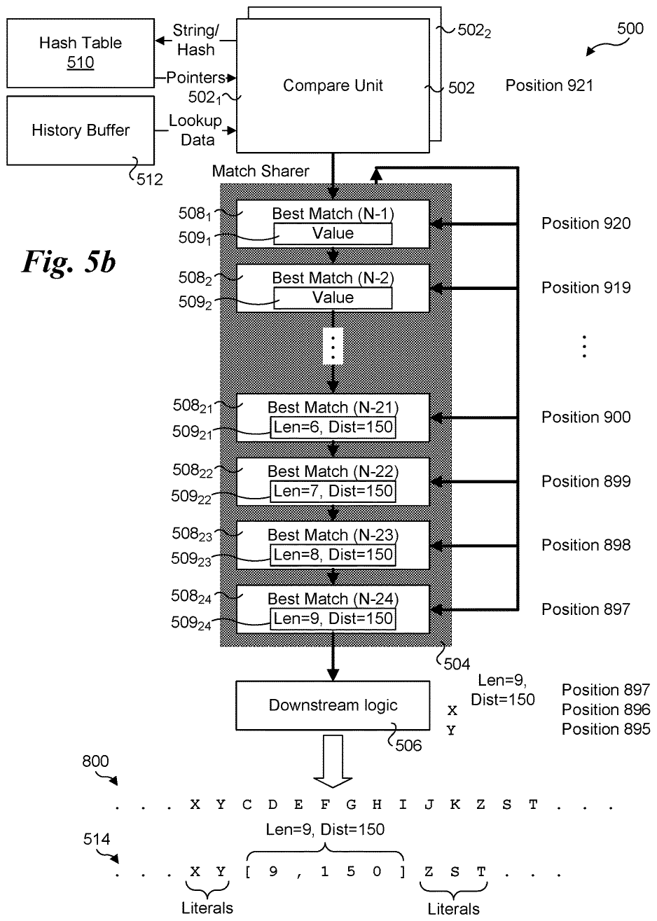

FIG. 5 shows a diagram of an apparatus 500 including one or more compare units 502, a match sharer 504, and downstream logic 506. Match sharer 504 contains a pipeline of the best (so far) matches for the most recent positions, which are identified via operations implemented in respective logic blocks and stored in respective registers, as described below. The elements of the match pipeline are called “entries,” with the example in FIG. 5 including M entries respectively labeled “Best Match (N-1),” “Best Match (N-2),” “Best Match (N-3),”. . . “Best Match (N-M), which are also associated with respective logic blocks 508₁, 508₂, 508₃, . . . 508_{M} and respectively stored in registers 509₁, 509₂, 509₃, . . . 509_{M}.

As further shown in FIG. 5, compare unit(s) 502 access a hash table 510 and a history buffer 512. As described in further detail below, the compare unit(s) provide a string or an index comprising a hash of the string to look up a matching entry in hash table 510 at the index. When provided with a string, the hash table will hash the string to obtain the index. The matching entry includes zero or more pointers identifying forward match locations in history buffer 512 to be compared with a portion of the byte stream in a lookahead buffer. Data proximate to the forward match locations are read from the history buffer by the compare unit(s) and are depicted as lookup data in FIG. 5.

There are several compare operations being processed in parallel. Compare results derived from the compare operations are input to the match sharer and are called “inputs.” Depending on the compression mode, there may be multiple inputs for the same position, single inputs for each of several positions, or some combination of the two. For simplicity, the following examples describe and illustrate cases of multiple matches at a single position and multiple matches at multiple positions.

As illustrated in FIG. 5, the output from compare unit(s) 502 is provided as inputs to match sharer 504. There is a “score function” that determines the score or “goodness” of a particular match. Matches get better scores if they are larger or closer to the current position.

The inputs are sorted so that the inputs with the best scores are considered first. The score function used in the sort may be different from the score function used to update an entry. Also, when sorting, if the inputs are from different positions, the relative positions also need to be factored into the score. The match sharer then loops through all the entries in the pipeline and conditionally updates them. This is described here as a “loop”, but in the hardware, each update is done at the same time in parallel using logic in logic blocks 508₁, 508₂, 508₃, . . . 508_{M}.

The sorted compare results are shared as inputs for the entries at positions N-1, N-2, N-3, . . . N-M and respectively evaluated by logic blocks 508₁, 508₂, 508₃, . . . 508_{M}. For an entry, the logic for the entry looks through the (sorted) inputs to find the first input whose match includes the position of the entry. The score for that input is computed, and it is compared with the score for the entry that is currently stored for a given position. If the input has a better score, the entry is updated with the input.

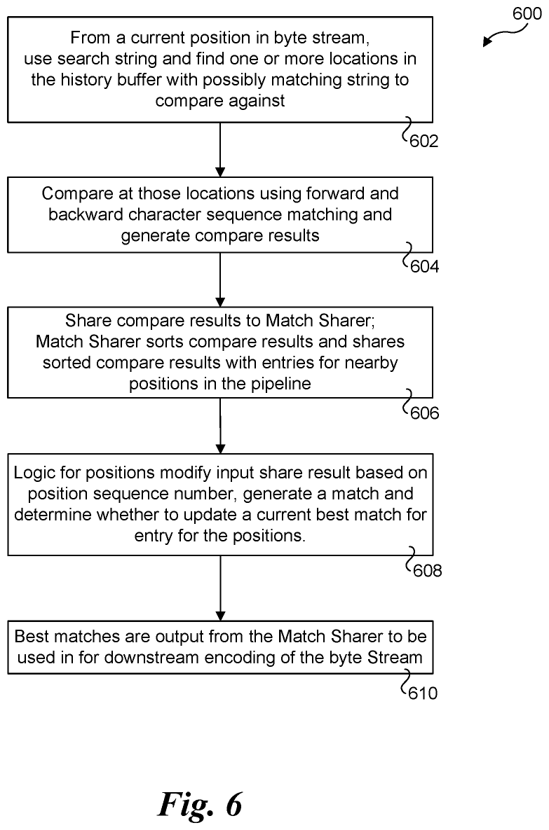

FIG. 6 shows a flowchart 600 illustrating operations performed using apparatus 500, according to one embodiment. In a block 602, from a current position in the byte stream a search string comprising a sequence of characters moving forward from a current position is used to find one or more locations in the history buffer with a (possibly) matching string to compare against. As described below, these locations are referred to as forward match locations. For a given search string (sequence of characters beginning at a current position N for apparatus 500 moving forward), the search string will be hashed using hash function to obtain an index to be used to look up an entry in hash table 510 at the index containing one or more pointers to the forward match locations in the history buffer.

In a block 604, compare operations are made at the one or more locations using forward and backward character sequence matching, and compare results are generated. The compare results from block 604 are shared with the match sharer, which sorts the compare results and shares the sorted compare results with the entries for nearby positions in the pipeline, as shown in a block 606. In a block 608, logic for the positions modify the input share result based on the position sequence number, generate a match based on the modified input and determine whether to update a current best match for the entry positions. In a block 610 the best matches are output from the match sharer to be used for downstream encoding of the byte stream.

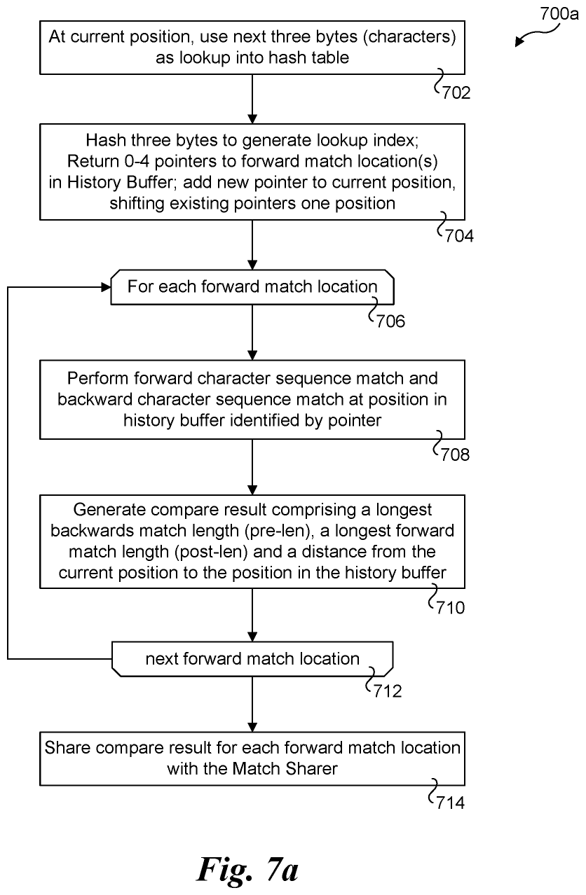

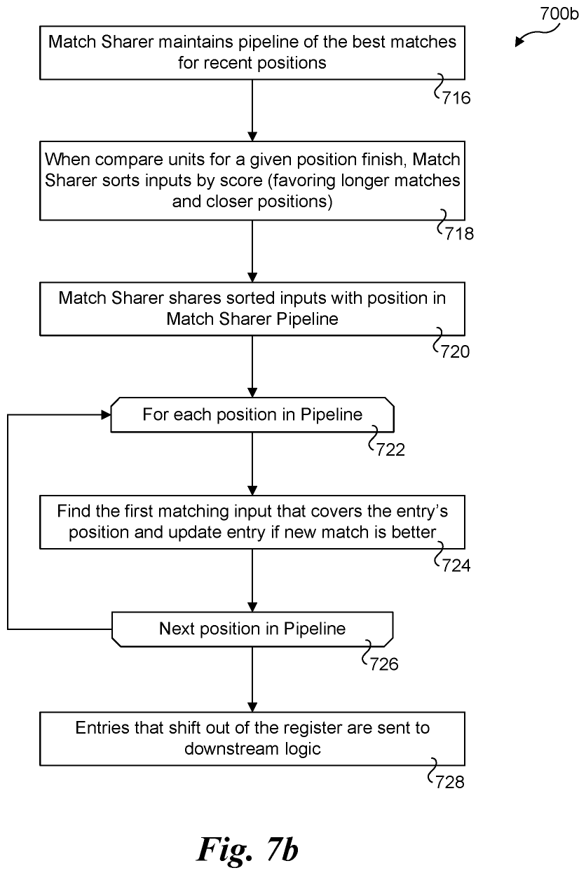

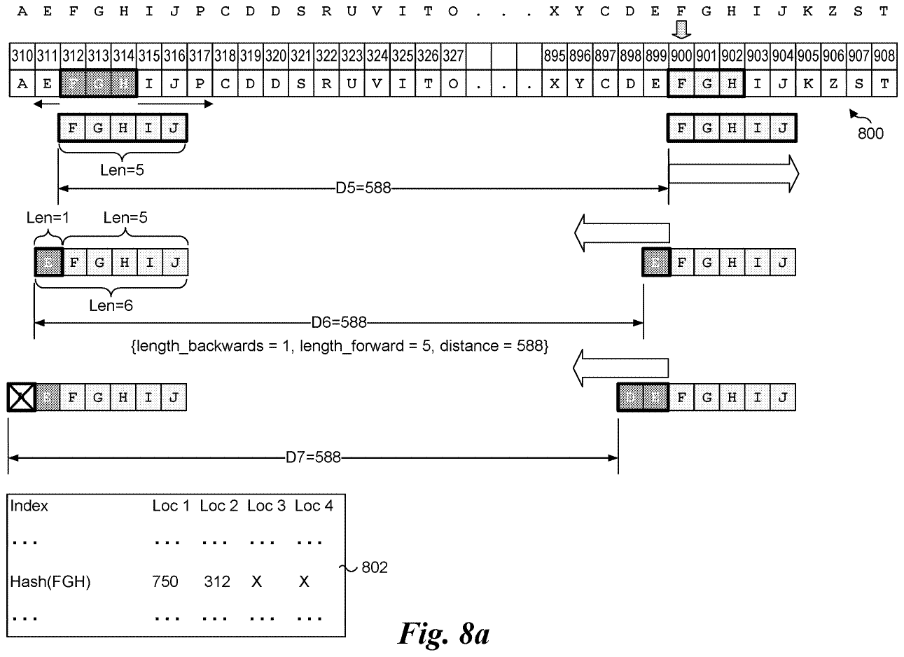

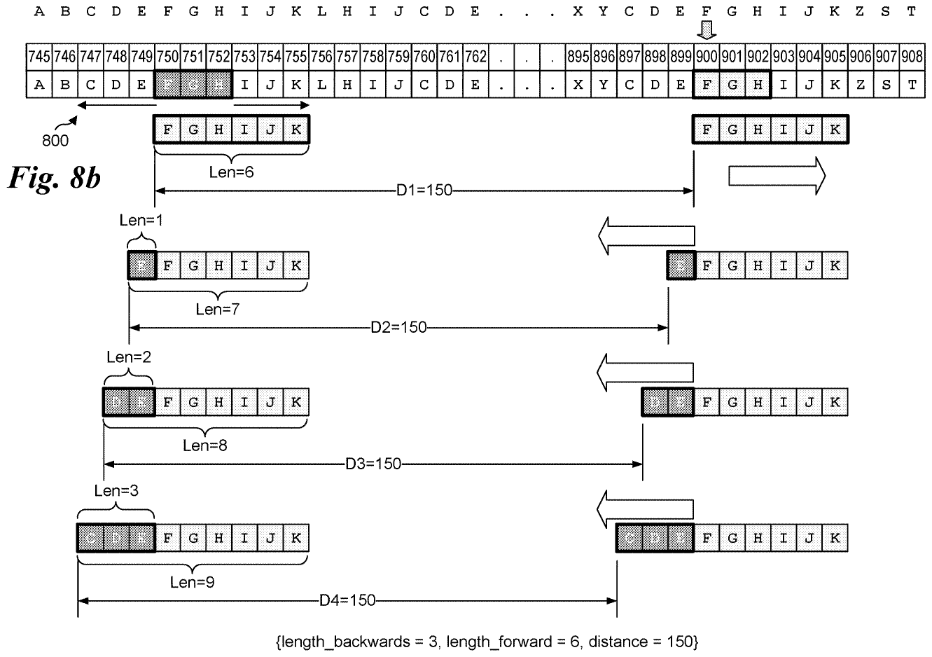

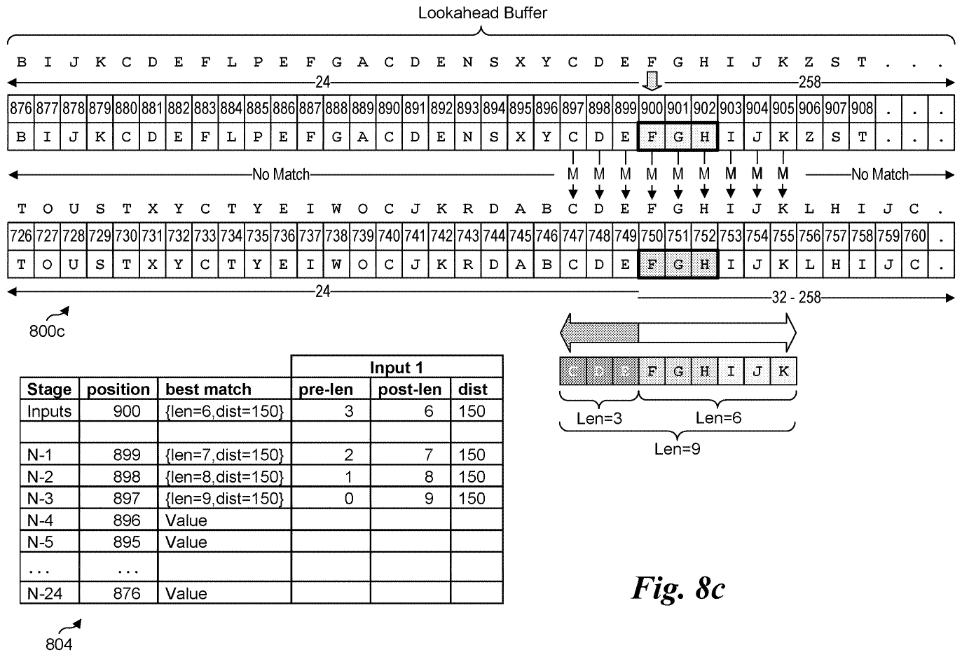

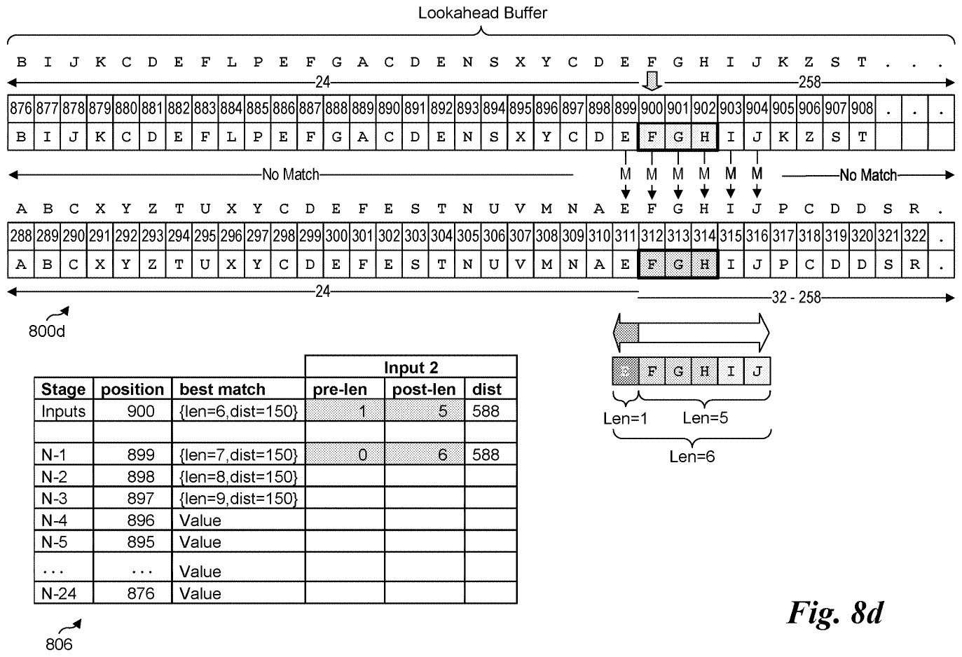

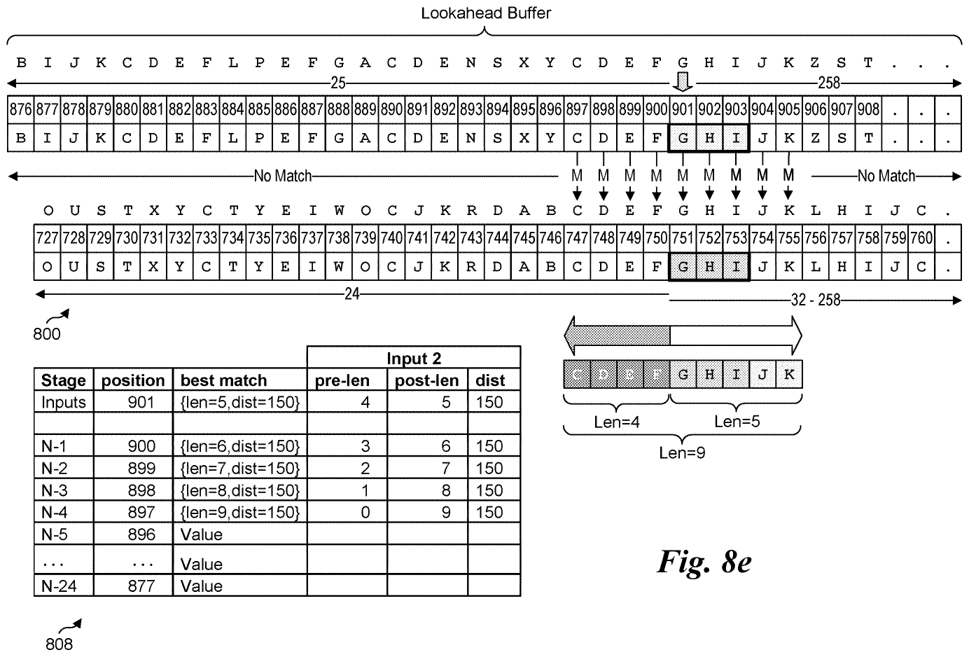

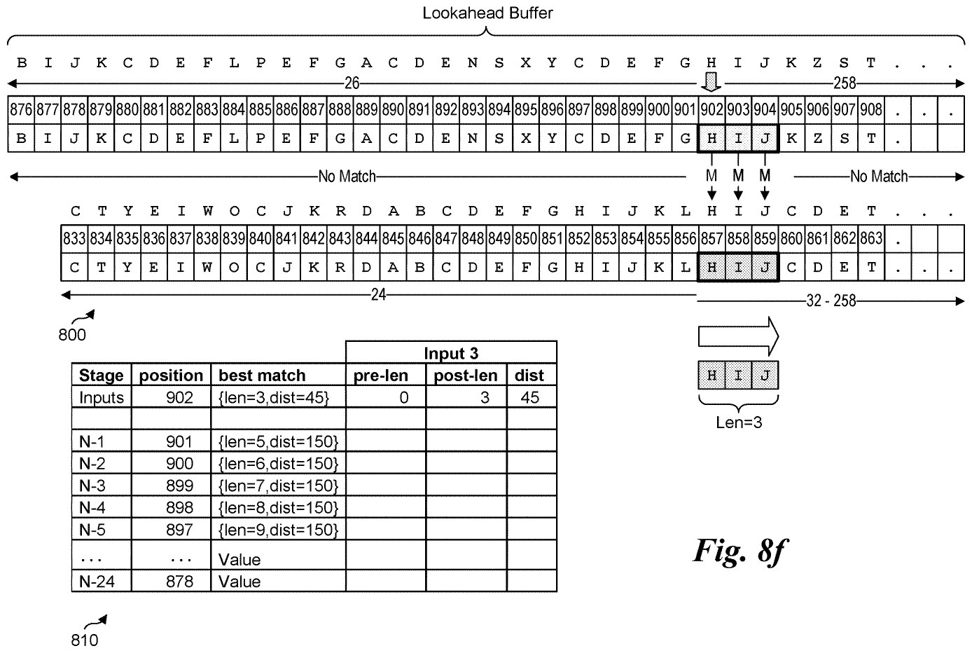

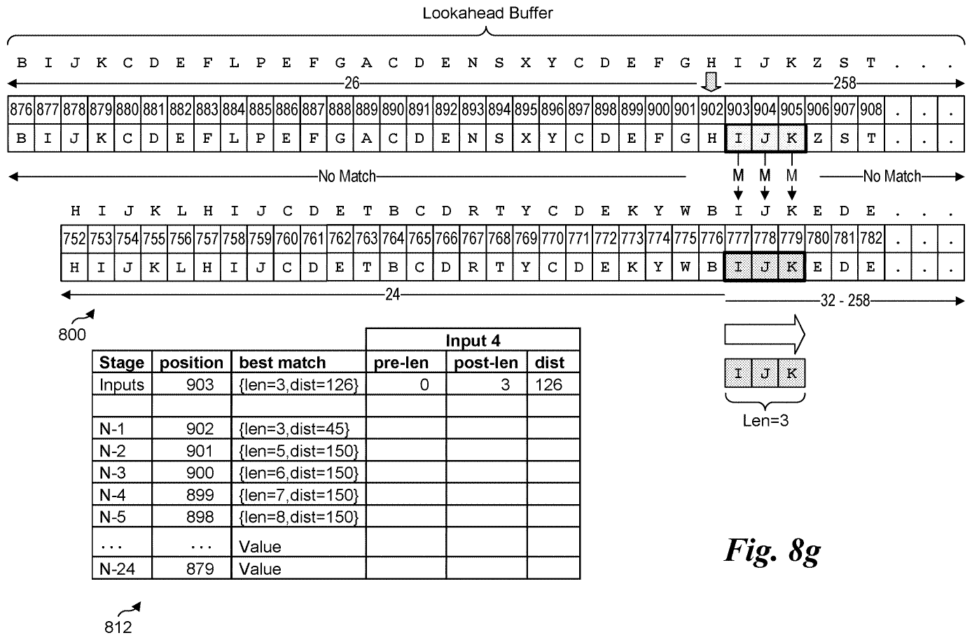

A more detailed explanation of the process is now provided with reference to flowcharts 700a and 700b of FIGS. 7a and 7b, and diagrams in FIGS. 5a, 5b, and 8a-8g. With reference to flowchart 700a, the process for a given cycle begins in a block 702 at a current position in the byte stream. The next three characters beginning at the current position are used for the forward search string, which are used for a lookup into the hash table. In a block 704 the three-byte sequence is hashed (e.g., using some hash function) to generate a lookup index. The index is used to identify an entry in the hash table that will contain 0-4 pointers to forward match locations in the history buffer. A new pointer to the current position will be added for the entry at the index, and any existing pointers will be shifted by one position, as further described below with reference to the hash table 802 in FIG. 8a. Initially, the hash table begins empty and as the current position advances from the beginning of the byte stream, new entries will be added to the hash table based on the hashed indexes of the three-byte sequences beginning at respective positions in the byte stream. When the location data for an entry is empty, there will be no pointers to return.

At the top of FIGS. 8a and 8b is a byte stream of characters 800 beginning at character position 310 at the left in FIG. 8a, a current position 900, and maximum position of 908. For simplicity, the positions in several of the Figures herein range from 288-908; it will be recognized by those skilled in the art that the illustrated portions of the byte stream are somewhere in the history buffer.

FIG. 8a further shows a hash table 802 including a first column containing an index and four location columns or fields labeled as Loc 1, Loc 2, Loc 3, and Loc 4 respectively containing location indicia for four locations in the history buffer. The use of four location columns/fields for each entry is exemplary and non-limiting, as other numbers of location columns/fields may be used. In one embodiment the location indicia is a character location (e.g., pointer to the position of a first character of a potentially matching string) in the history buffer; for simplicity position numbers are used in the following examples. Alternatively, the location indicia also may be an offset value in another embodiment. The number of entries in the hash table can vary, depending on the implementation. In one example, there are 1024 entries. Initially, all the entries are empty. In the embodiment of hash table 802, the location in Loc 1 is the closest location to the current position such that any existing location(s) in the entry is/are shifted to the right when the location indicia for the current position is added at the end of block 704. When there are four current locations values for a given entry, the locations in Loc 1, Loc 2, and Loc 3 are shifted one position to the right, evicting the previous location at Loc 4, and the new location is added at Loc 1.

Since the hash table will have some finite number of entries, such as 1024, there will be instances where different 3-character sequences will hash to the same index. Thus, for a given 3-character string, some (or even all) of the locations in Loc 1, Loc 2, Loc 3, and Loc 4 for the entry at the index obtained using a hash of the 3-character string may not contain the 3-character string. However, under the examples herein such occurrences are not shown.

In this example, the search string is ‘F G H’ and the lookup of this string (using a hash of the string to obtain an index) in hash table 802 finds an entry with location indicia for an instance of ‘F G H’ located at character position 750 and an instance of ‘F G H ’ located at character position 312. As of the current location 900, the values for Loc 3 and Loc 4 in hash table 802 are depicted as an ‘X’ indicating they are empty.

As shown in the loop of flowchart 700a delineated with start and end loop blocks 706 and 712, the operations in blocks 708 and 710 are performed for each forward match location for which a pointer is returned in block 704. Under one mode utilizing multiple compare units, a respective pointer would be returned to a respective compare unit, and the operations in the loop in flowchart 700a would be implemented using the multiple compare units in parallel.

In block 708 a forward character sequence match and a backward character sequence match at the position in the history buffer identified by the pointer is performed. These are also called forward and backward compare operations. An example of the forward and backward compare operations are shown in FIG. 8c. The compare unit(s) share a lookahead buffer that is depicted at the top of FIG. 8c. The lookahead buffer operates as a sliding window that buffers a portion of byte stream 800. In the illustrated embodiment, that portion includes the character at the current position (900) plus the next 258 characters moving forward and 24 characters moving backwards. Under the diagrams herein, the positions with the lower numbers are located in the byte stream before the positions with higher numbers. As such, moving forward means increasing the position number, while moving backwards means decreasing the position number. As discussed below, in a mode where respective compare units are used for processing four sequential current positions in parallel, the lookahead buffer may include the next 261 characters from the first of the four sequential current positions.

The nearest match for ‘F G H’ is at position 750 in the history buffer. For this location, the characters at position 750 plus the next 32-258 characters in the forward direction and 24 characters in the backward direction are read from the history buffer, as depicted by character sequence 800c. Since the likelihood of a forward match of more than 32 characters is small (see FIG. 2 and discussion above), in one embodiment blocks of 32 bytes are read from the display buffer. In an alternative embodiment, an entire block of the next 258 characters will be read.

As illustrated in FIG. 8c, the character sequence in the lookahead buffer and the character sequence 800c from the history buffer are aligned such that the compare unit can compare bytes from the lookahead buffer and history buffer. The forward match or compare operation determines the length of the sequence of characters beginning from the current position (900) in the lookahead buffer that match a sequence of the characters read from the history buffer beginning at the match location (750). In this example the forward match length is 6 characters. The backward match or compare operation is similar, but the sequences are taken in a backwards order beginning at the character positions immediately before the current position (899) and immediately before the forward match location (749). In this example, the backward match has a length of 3 characters. The combined forward and backward lengths have a length of 9 characters.

In block 710, the compare unit generates a compare result comprising a longest backwards match length (pre-len), a longest forward match length (post-len) and a distance (dist) from the current position to the position in the history buffer. Examples of the compare results for two forward match locations are shown in FIG. 5a and FIGS. 8a and 8b and are described below with reference to flowchart 700b in FIG. 7b.

The same operations for the loop in flowchart 700a are performed for the second forward match location at character position 312. As illustrated in FIG. 8d, as before the character sequence in the lookahead buffer and the character sequence 800d from the history buffer are aligned such that the compare unit can compare bytes from the lookahead buffer and history buffer. The forward match or compare operation determines the length of the sequence of characters beginning from the current position (900) in the lookahead buffer that match a sequence of the characters read from the history buffer beginning at the match location (312). In this example the forward match length is 5 characters. The backward match or compare operation is similar, but the sequences are taken in a backwards order beginning at the character positions immediately before the current position (899) and immediately before the forward match location (311). In this example, the backward match has a length of 1 character. The combined forward and backward lengths have a length of 6 characters.

To support concurrent access to the history buffer, in one embodiment the history buffer has multiple ports, each of which is accessed using a respective compare unit. For example, in the case of four compare units the history buffer has four ports. This enables portions of the byte stream at different locations in the history buffer to be accessed in parallel. Thus, in the example of forward match locations at positions 750 and 312, the compare operations shown in FIGS. 8c and 8d are performed in parallel by two compare units. In a similar manner, compare operations for four forward match locations can be performed in parallel using four compare units.

In a block 714, the compare result for each forward match location is shared with the match sharer.

When there are multiple forward match locations (with locations identified by respective pointers) and there are multiple compare units, the operations described and illustrated below may be performed in parallel.

In a block 716 of flowchart 700b, the match sharer maintains a pipeline of the best matches for recent positions. As shown in a block 718, when the compare unit(s) for a given position finish, the match sharer sorts inputs by score, which favors longer matches and closer positions. In a block 720 the match sharer shares the sorted inputs with the positions in the pipeline. As depicted by start and end loop blocks 722 and 726, the operation of block 724 is performed for each position in the match sharer pipeline. In block 724, the first matching input that covers that entry's position is found and the entry at that position is updated if the new match is better than the existing match for the entry. In an alternative embodiment, the logic for the entry's position considers all the applicable inputs, computes a score for each of them (and itself) and then picks the one with the best score. In a block 726, entries that shift out of the register (used for the match sharer) are sent to the downstream logic (e.g., downstream logic 506 in FIGS. 5, 5a, and 5b).

These operations are illustrated in the diagrams of FIGS. 8c, 8d, 5a and 5b. For a pipeline with M entries, there are M score and update operations, which are done in parallel in one embodiment. As shown in FIGS. 8b and 8c, the compare result for match location at position 750 has a backward length of 3 characters ‘C D E’, a forward length of 6 characters ‘F G H I J K’, and a distance=150 In the tables in FIGS. 8c-8g, including table 804, the backward length is shows as a “pre-len”, while the forward length is shown as a “post-len” and the distance as “dist.”

As shown in FIG. 5a, in this example we have compare results from two compare units 502₁ and 502₂, respectively labeled “Input 1” in table 804 of FIG. 8c and labeled “Input 2” in a table 806 in FIG. 8d. The compare result for Input 1 from compare unit 5021 that is shared with match sharer 504 is {pre-len=3, post-len=6, dist=150}, while the compare result for Input 2 from compare unit 502₂ that is shared with match sharer 504 {pre-len=1, post-len=5, dist=588}. These are both for current position 900.

In one embodiment the score for inputs is a function of the longest post-length for the input and the distance for the input, where longer post-lengths and lower distances score higher. Since post-length of Input 1 (6) is greater than the post-length of Input 2 (5), the longest post-length sub-score is higher for Input 1. Likewise, since the distance (150) for Input 1 is less than the distance for Input 2 (588), Input 1 is scored higher for the distance sub-score than Input 2. Based on the higher score, Inputs 1 and 2 are sorted such that Input 1 is first.

In addition to pre-len, post-len, and dist columns, Table 804 includes a Stage column, a position column, and a best match column. The Stage column is for stages in the match pipeline including for the current position, which provides the inputs, followed by positions N-1, N-2, N-3, N-4, N-5, . . . N-24. The position column identifies the position in the byte stream, and the best match column includes the best match at each position and pipeline stage after the updates, as applicable.

The following describes how the logic in the logic block for each entry works, according to the illustrated embodiment. The input (for Input 1) of {pre-len=3, post-len=6, dist=150}is shared with the entries in the pipeline. The logic block associated with the entry at each position knows its position. The input shared with a given entry is modified by the logic block for the entry by subtracting the difference between the current position and the entry position from the pre-len and adding the entry position to the post len when the modified pre-len is >=0. The logic for each entry in the pipeline decides whether the modified input applies to that entry. The modified input applies if the pre-len is >=0 and the post-len is >=3, where 3 is the minimum match length. In alternative embodiments the minimum match length is an integer greater than 3.

Let's consider the entry at N-1 for Input 1 in table 804. The position is 899. The operations are performed by logic block 5081. The pre-len of 3 for Input 1 is decremented by 1, and the post-len is incremented by 1, resulting in a pre-len=2 and post-len=7 at dist=150. Since the pre-len is >=0 and the post-len is >=3, the modified input for entry N-1 applies. The best match for an entry only considers the post-len for the len and then adds the dist to form a {len,dist}pair. For the entry for N-1, the best match is {len=7,dist=150}. In this example, it is presumed that the best match {len=7,dist=150}is better than the prior best match for entry N-1 and so the entry for N-1 is updated to {len=7,dist=150}.

The entries for positions N-2 and N-3 are processed in a similar manner by logic blocks 508₂ and 508₃, respectively. For entry N-2, the pre-len is 1 (3-2) and the post-len is 8 (6+2) at a dist=150. The new best match for entry N-2 is {len=8,dist=150}. For entry N-3, the pre-len is 0 (3-3) and the post-len is 9 (6+3) at a dist=150. The new best match for entry N-3 is {len=9,dist=150}.

Now consider what happens for entry N-4. The pre-len in the modified input for entry N-4 is 3-4=−1, which is not >=0. Thus, the modified input does not apply to entry N-4. Since the modified entry does not apply, the current best match, labeled “Value”, is not updated. “Value” here would be either a literal character or a {len,dist} pair. In a similar manner, the modified inputs for each of entries N-5, N-6, . . . N-24 would have a negative pre-len and thus would not apply to any of these entries. In is noted that “Value” might be updated with other inputs if those inputs are applicable.

FIG. 8d shows a table 806 corresponding to Input 2, which is {pre-len=1, post-len=5, dist=588}. Since this is sorted second, the only modified entries that might be considered would be for entries for which modified entries from Input 1 did not apply. The modified input for entry N-1 is pre-len=0, post-len=6. These values are shown with gray shading to indicate that while the modified input meets the application criteria, there a modified input for Input 1 that already was applied so the modified input for entry N-1 for Input 2 is not used. Since the pre-len for the modified inputs for entries N-2, N-3, . . . N-24 are negative, none of the modified inputs for these entries applied. For illustrative purposes, the best matches in the best match column are the same for tables 802 and 804.

FIG. 5a shows the state of the match pipeline after the operations for the current position 900 have been completed. As shown, the best matches for positions N-1, N-2, and N-3 are the same as shown in table 804 of FIG. 8c. The best match values for positions N-4 and N-5 are shown as literals ‘Y’ and ‘X’, with the best match values for the remainder of the positions N-6 . . . N-24 depicted as “Value.”

For the next set of parallel operations, the position for N is increased by 1 and the entry at position N-24 (876) in the match sharer would be shifted out to the downstream logic. At position 901, the forward search will look for forward character sequences beginning with the character string ‘G H I’. At a minimum, the character sequences that are considered are at least 3 characters in length. Thus, when the pipeline is advanced one character at the end of the processing at a current position to the next current position N, the Value for position N-24 will be the current best match value at that time.

FIG. 5b shows the entries in the match sharer when the current position is 921. The entries for positions N-1 through N-21 are depicted as ‘Value’—for this example those values are irrelevant. The entries at positions N-22 (899), N-23 (898), and N-24 (897) are respectively {Len=7, Dist=150}, {Len=8, Dist=150}, and {Len=9, Dist=150}. Now, presume that entry for position N-24 (897) has been shifted out of match sharer 504 and received by downstream logic 506, along with the entries for positions 896 and 895.

Downstream logic comprises logic in the apparatus the is used to generate the encoded compressed byte stream. In the example, the encoding uses DEFLATE, but it will be recognized by those skilled in the art that DEFLATE is merely exemplary and non-limiting as other compression algorithms and encodings may be used. Generally, downstream logic may use various schemes, such as a “greedy” scheme, a “lazy” scheme, or some other scheme to process the inputs it receives from match sharer 504, as are known in the art. For purposes herein, the particular encoding algorithm and/or scheme is outside the scope of the present disclosure.

In this example, a greedy scheme is used where the downstream logic performs encoding without looking forward in the stream of inputs it receives. We begin with the literals ‘X’ and ‘Y’, which are respectively encoded as literals ‘X’ ‘Y’ in compressed byte stream 514. Next, {Len=9, Dist=150}is considered. Under one aspect of a greedy approach, downstream logic 506 is configured to recognize an instance of a {Len, Dist}pair following a literal add the {Len, Dist}pair as {Len, Dist} to the compressed byte stream. Downstream logic will then skip the number of positions equal to Len. In this example, Len=9 at position 897, the next 9 inputs from match sharer 504 are skipped, with the position in the byte stream being advanced to position 906. The next three characters ‘Z’, ‘S’, ‘T’ are encoded as literals. In this example, it is presumed there is no instance of ‘Z S T’ at any of the locations for the entry in the hash table at the index obtained by hashing ‘Z S T’.

In addition to the mode that processes one position at a time (per cycle), there is a mode that uses up to four compare units to generate compare results for four sequential positions in parallel starting with a current position. The compare results for each of the four sequential positions are shared with the match sharer in a similar manner to when compare results from multiple forward match locations using the same current position are shared. Another embodiment generates compare results for two sequential positions with up to two forward match locations for each position.

FIGS. 8e, 8f, and 8g respectively show forward and backward character sequence match operations for positions 901, 902, and 903, which would be performed using respective compare units in parallel with the same operations for position 900 discussed above. When there are four sequential positions processed in parallel, only a single forward match location is used for each position.

Referring to FIG. 8e, the forward search string for position 901 is ‘G H I’, and Loc 1 for the hash table entry at the hashed index for ‘G H I’ is location 751 at a distance=150 from position 901. The forward character match operation identifies a longest forward match of five characters (post-len=5), and the backward character match operation identifies a longest backward match of four characters (pre-len=4), at a distance of 150. Thus, the compare result for position 901 is {pre-len=4, post-len=5, dist=150}and is labeled as Input 2 in table 808. The modified inputs for entries N-1 (position 900), N-2 (position 899), N-3 (position 898) and N-3 (position 897) are {pre-len=3, post-len=6, dist=150}, {pre-len=2, post-len=7, dist=150}, {pre-len=1, post-len=8, dist=150} and {pre-len=0, post-len=9, dist=150}, respectively. The resulting best matches for the entries at positions 889, 888, and 887 are {Len=7, Dist=150}, {Len=8, Dist=150}, and {Len=8, Dist=150}, respectively, which in this example are identical to the best matches for the entries for positions 899, 898, and 897 using position 900 and shown in FIG. 5a. The best match for the entry at position 900 has been updated to {Len=6, Dist=150}.

Note that the inputs also need to identify which position it is for. For example, if you had two inputs that both have a pre-len of 3, then if the positions for the matches are both 900, then both would apply to the same entries, but if one was from position 900 and the other was 901, then there would be an entry that one input would apply to and the other would not.

As shown in FIG. 8f, the forward search string for position 902 is ‘H I J’. Loc 1 for the entry at the hashed index for ‘H I J’ location 857. Notice in this example, since the nearest occurrence of ‘H I J’ to position 902 in the byte stream (and history buffer) begins at location 857, the occurrence of ‘H I J’ at position 752 will not be used. The result of the forward and backward character sequence match operations is a forward length of 3 characters and a backward length of zero at a distance of 45. Thus, the compare result input as Input 3 to the match sharer from compare unit 3 for position 902 is {pre-len=0, post-len=3, dist=45}. As shown in table 810, since the pre-len=0 there will be no modified inputs that apply for the entries for positions 901, 900, 889, . . . 878 as shown in table 810.

A similar compare result will be generated for position 903. As shown in FIG. 8g, the forward search string for position 903 is ‘I J K’. Loc 1 for the entry at the hashed index for ‘I J K’ is location 777. The result of the forward and backward character sequence match operations for position 903 and location 777 is a forward length of 3 characters, backward length of 0, at a distance of 126, resulting in an Input 4 of {pre-len=0, post-len=3, dist=126}from compare unit 4 for position 903. As shown in table 812, since the pre-len=0 there will be no modified inputs that apply for the entries for positions 902, 901, 900, . . . 879.

The different modes have relative advantages and disadvantages. When four compare results are generated for four forward match locations for the same position, there may be an increased likelihood of finding a longer forward+backward match than when processing four sequential positions in parallel. Processing four sequential positions in parallel will result in processing the byte stream four times faster, or at the least as applied with the generating the best matches that are output from the match sharer. The node that processes two positions with two forward match locations for each is faster than the single current position mode and may identify longer forward+backward matches than the four sequential position mode.

### Selecting Positions for Comparisons

In the foregoing examples employing match sharing, there are 4 parallel pipelines such that at most 4 positions can be processed in a given cycle. Where speed of compression is valued more highly than compressed size, it may be desirable to increase the speed further, e.g. to 6 or 8 bytes per cycle. Under the embodiments that follow, the number of positions that are to be processed during a given cycle is greater than the number of pipelines.

For example, consider an implementation employing 4 parallel pipelines. When processing more than 4 positions in parallel, the excess positions are marked as “skipped” and are not processed through the compare pipelines. For example, in an 8 position/cycle mode, 4 positions are skipped and 4 positions are processed.

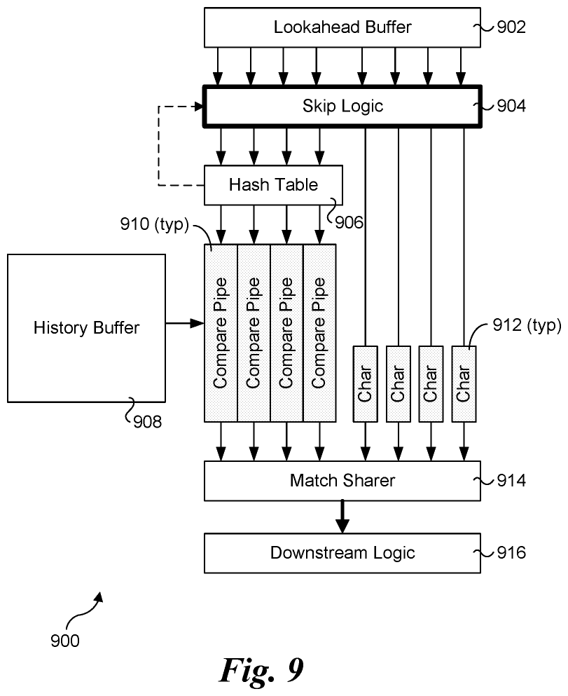

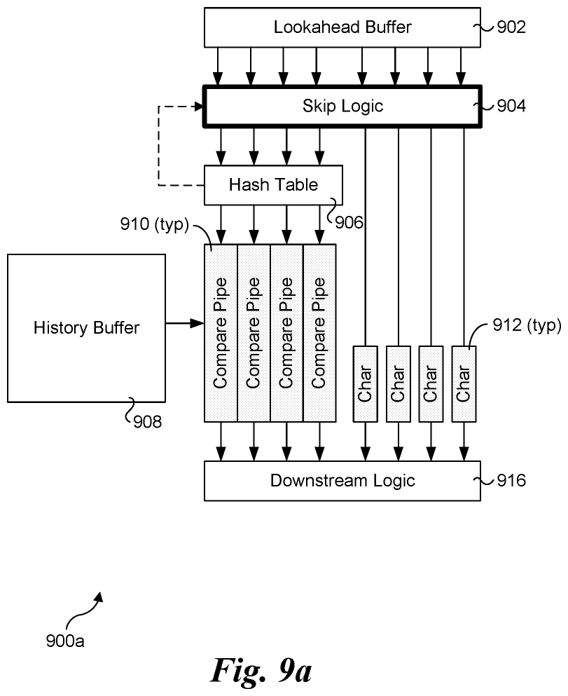

FIG. 9 shows a diagram 900 illustrating an implementation employing 4 parallel pipelines that processes 8 positions per cycle, with 4 positions being skipped. The components include a lookahead buffer 902, a skip logic block 904, a hash table 906, a history buffer 908, 4 compare pipes 910, four character buffers 912, a match sharer 914, and downstream logic 916. In one embodiment, compare pipes (or pipelines) are implemented with compare units, such as described and illustrated above. Likewise, match sharer 914 and downstream logic 916 are similar to the match sharer and downstream logic embodiments discussed and illustrated above.

FIG. 9a shows a diagram 900a illustrating an alternative implementation under which the match sharer is not used. In this embodiment, the outputs from compare pipes 910 comprise inputs to downstream logic 916. Also, character buffers 912 are used to buffer characters that are provided as inputs to downstream logic 916 in parallel with the inputs from the compare pipes.

A novel aspect is deciding which positions to place in which category so that the compression ratio is acceptable. In one embodiment, we select compare-eligible positions based on permutation ordering that maximizes match-sharing likelihood while avoiding hash bank conflicts. The selection logic itself cannot be too complex as it needs to operate at very high speeds and ensure it won't be a new bottleneck.

One of the most expensive (in terms of area and power) operations in compression is the compare or matching operation. To perform, for example, 4 compares in parallel requires with a history buffer with 4 read ports, or multiple copies of the history buffer, as well as the logic to perform the comparisons based on the data read from the history. As the history buffer is large (e.g., 4 kB to 32 kB), increasing the number of compare operations that can be done at the same time is expensive. What would be advantageous is to increase the number of positions that are processed in parallel without increasing the number of compare pipelines. This is what the position selection solution provides.

An important data structure for compression is the hash table. As discussed above, the hash table is used to take the current data (i.e., the data starting at the given position) and determine a location in the history buffer against which to compare. Essentially, the data at the current position is hashed to an index into the table, and then a location in the history buffer is read from that index. The hash table essentially holds possible locations in the history buffer where matches can be found relative to the bytes in the current positions, which are sent to the compare pipelines to determine the longest/best match.

To avoid making the hash table multi-ported, the area can be minimized by using a banked hash table. For example, by dividing the hash table into 16 (single-ported) banks, there is a high likelihood that if the data is different at two different positions, that the hashed indices fall in different banks, and so both can be fetched at the same time. In the case of a hash collision (i.e. where one position hashes to the same value as an earlier position, within the group of positions being processed in parallel), the earlier position takes precedence, and the later position receives a “null pointer” (i.e., the same result as if that hash table entry was empty).

Statistically, shorter matches are more common than longer matches. Thus, it is more likely that a match would be shared with nearby positions and less likely that it would be shared with positions further away.

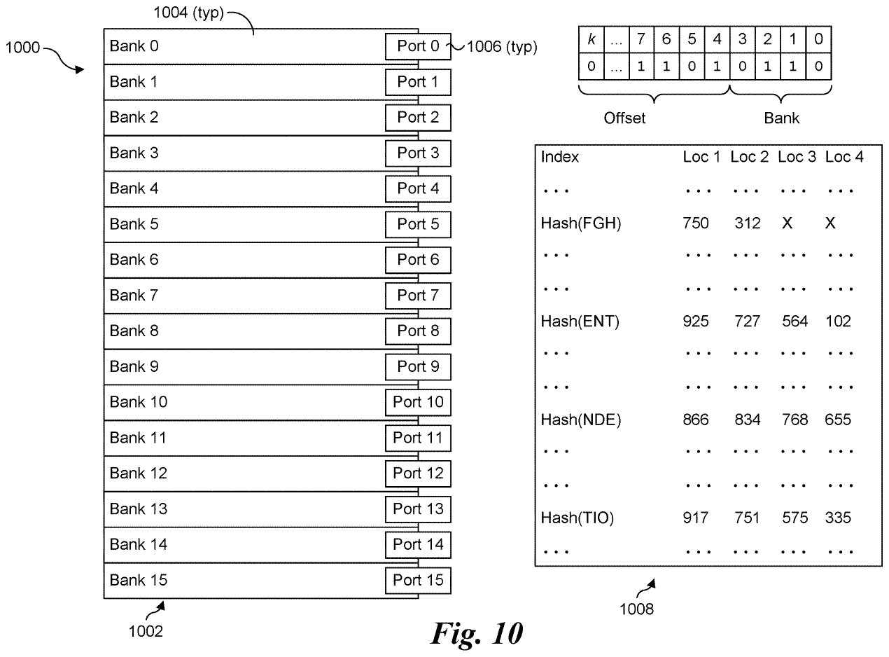

FIG. 10 shows a diagram 1000 illustrating an implementation of a hash table in memory 1002 including 16 banks 1004 with respective ports 1006. Hash table 1008 is a logical representation of a flat hash table showing hashes for examples ‘FGH’, ‘ENT’, ‘NDE’, and ‘TIO’ would be logically located at respective indexes in the hash table with the entry at each index including one or more pointers or the like pointing to one or more locations in the history buffer. This example shows four locations (Loc 1, Loc 2, Loc 3, and Loc 4) which is exemplary and not limiting as an entry can include one or more locations. From the logical hash table perspective, the location entry pointers are added and (as applicable) updated in the same manner as described and illustrated above.

The way the location data (e.g., pointers) in the hash table are stored and accessed is different than a flat hash table, which is limited to looking up one hash index at a time (presuming a single port). Under the embodiment illustrated in FIG. 10 the binary value for the hash index is used to locate the corresponding entry in memory 1002. In this example, the 4 lowest significant bits (LSBs) are used to identify the bank in which the entry is stored, with the remaining most significant bits (MSBs) used to identify the offset index within that bank. In the example, k is the highest MSB, and may generally be 7 or more (noting the bit positions shown begin at ‘0’ rather than ‘1’). For example, for an implementation with 4 LSBs, 4-7 MSBs would be used to respectively store 16, 32, 64, and 128 entries per bank.

Since each bank includes its own port, for this 8 position example, hash table entries for up to 8 positions can be fetched in parallel. In cases where the LSBs for the hash are the same there will be a hash collision, which are addressed in the manner described below.

Call the set of positions being processed in parallel a “batch”. The following description will assume a batch size of 8 and 4 compare pipelines. Of course, other combinations are also possible, e.g. a batch size of 6 with 4 compare pipelines, etc.). In general, the number of positions in a batch will be an integer N, while the number of compare pipelines will be an integer M wherein M<N.

For example, one batch of positions might be from 1024 to 1031, so that the next batch goes from 1032 to 1039. The positions within a batch will be labeled by their offsets with respect to the first position, e.g., the positions will be described as 0 . . . 7, regardless of their absolute offsets within the input data.

In this example, we want to select 4 positions from the batch to be processed in the compare pipelines, and 4 positions to be “skipped” (not processed through the compare pipelines). One thought is to process the even positions (0, 2, 4, 6) and skip the odd positions (1, 3, 5, 7). The problem with doing this is that some of the processed positions might be skipped anyways, due to hash table collisions, so that compare pipe is “wasted”. It might be the case that one of the odd positions would not have had a hash table collision, and so it could have been processed in place of the even position that had the collision.

Another approach would be to hash all 8 positions and process the first 4 that don't have collisions. The problem here is that you would often end up processing positions 0-3 and skipping 4-7, which reduces the effectiveness of the Match Sharing unit. To avoid this, in one embodiment we take the first 4 that don't have collisions when we consider the positions in a permuted order. For example, one could start at 0 and then add new offsets so as to minimize the size of the gaps. This would make the next position 4 (so the gaps are 1-3 and 5-7). Then the next two positions would be 2 and 6, etc. This would result in the order: 0, 4, 2, 6, 1, 5, 3, 7. Then, for example, if there were no conflicts, we would be doing matching at positions 0, 2, 4, 6, and skipping 1, 3, 5, 7, so that each skipped position is adjacent to one that is not skipped (in this example). Of course, other permutations are possible. For example, one could alternate the above order with the same order with the two halves reversed: 1, 5, 3, 7, 0, 4, 2, 6. This would result in half the time the even positions taking precedence and half the time the odd positions taking precedence.

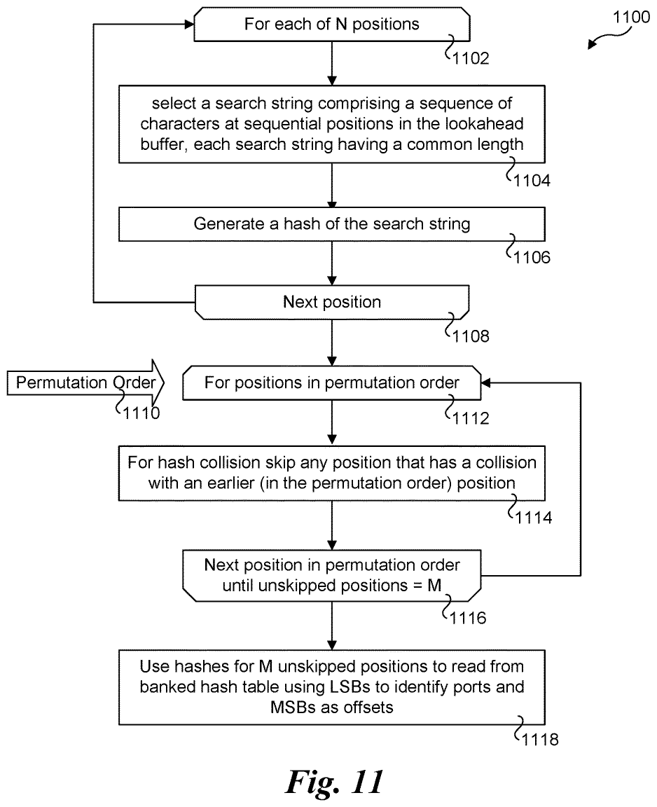

FIG. 11 shows a flowchart 1100 illustrating operations and logic for implementing a scheme combining use of permutations with consideration of hash collisions, according to one embodiment. As shown by start and end loop blocks 1102 and 1108, operations in blocks 1104 and 1108 are performed for each of N positions. While depicted as a loop, in one embodiments these operations are performed in parallel (or substantially in parallel).

In block 1104 a search string comprising a sequence of characters at sequential positions in the lookahead buffer are selected for the current position, with each search string having a common length. For example, in one embodiment the search string is the 3-character string beginning at the current position. In block 1106, a hash is generated for each search string using an appropriate hash function in a manner similar to that described above.

Next, the logic proceeds to a second loop including start and end loop blocks 1112 and 1116. The loop performs the operation in block 1114 in a permutation order 1110. As shown in block 1114, for a hash collision skip any position that has a collision with an earlier (in the permutation order) position. Hash collisions would occur if the LSBs for two or more hashes among the 8 hashes are the same. This second loop is continued until the number of unskipped positions=M.

In a block 1118 the hashes for those M unskipped positions are then used to read from the banked hashed table using the LSBs of each hash to identify the banks used, with the MSBs for the hashes being used as the index offset to read the location for the matching entry in the history buffer.

Let's consider a permutation order of 0, 4, 2, 6, 1, 5, 3, 7. Suppose there is a collision for positions 4 and 6, and there is a collision for positions 2 and 5, and the number of compare pipes M=4. Using the logic in block 1114 the resulting unskipped M positions would be 0, 4, 2, 1. The hashes for the search strings at these locations would be used to identify matching locations in the history buffer. For positions 6, 5, 3, and 7, the characters at these positions would be passed for further processing, either as inputs to the match sharer or inputs to the downstream processing logic as shown in the respective embodiments of FIGS. 9 and 9a discussed and illustrated above.

Alternate approaches may also be used. For example, varying whether the even or odd positions take precedence may also improve matching for semi-structured data. In most algorithms, the minimum match size is 3. Imagine that the data being compressed consisted of an array of DWORDS (4 byte words) containing sequential values. Thus, the byte stream might contain 01, 00, 00, 00, 02, 00, 00, 00, 03, 00, 00 00, etc. If all the matching occurred at even positions, so that it was looking at “01 00 00”, “00 00 02”, “02 00 00”, etc., it would find no matches. But if it was looking at odd positions, every other compare would be looking at “00 00 00”, and it would find many matches.

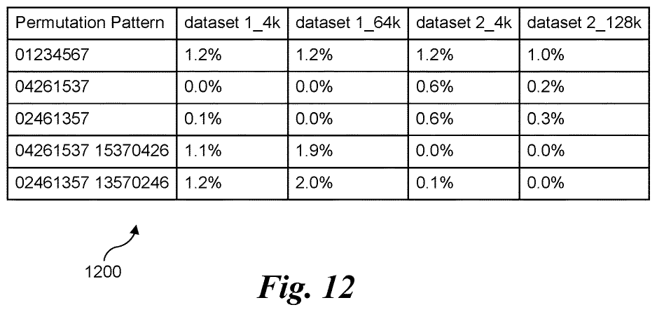

In the end, the best metric is to try a variety of permutation orders against a representative data set, and see which gives the best results on average. For example, we compressed four data sets (two different types of data, each with two different input sizes), and computed the average compression ratio. The values shown in table 1200 of FIG. 12 represent how much each value was as a percentage of the smallest value (within that column). The highlighted cells, which contain 0.0%, are for the permutation pattern that resulted in the smallest size for that data set. A value of 1.2%, for example, means that the average size was 1.2% larger than the smallest size.

The last two entries employed alternating permutation patterns. As demonstrated here, the alternating permutation 04261537 15370426 resulted in the smallest size for dataset 2_4k and dataset 2_128k.

To summarize, novel aspects of the embodiments include selecting which input positions to compare using a permutation order while skipping excess positions while still maintaining good compression ratio. By using adjacency-based match sharing, skipped positions can still benefit from nearby matches. By using a fixed number of compare pipelines with larger data block sizes that are processed in parallel, data compression throughput is increased without having to increase the number of compare pipelines. Using banked, single-ported hash tables coordinated with the permutation scheme and associated schemes for addressing hash collisions enables match patterns lookups of the hash table to be performed in parallel. Alternating permutation patterns may also be implemented to avoid pathological compression loss on structured data.

### Exemplary Systems and Implementation Environments.

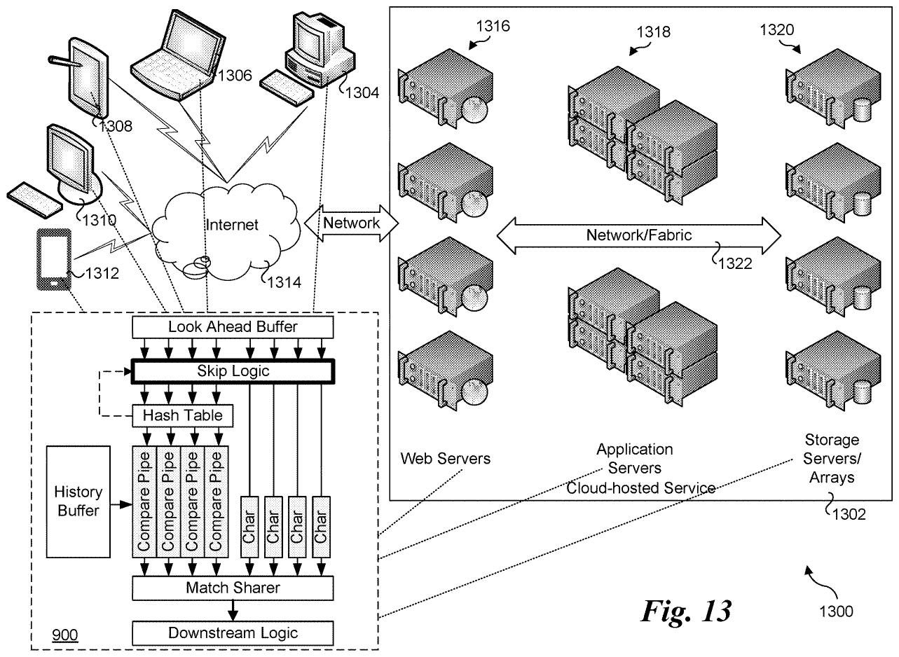

Exemplary systems and environments for which aspects of the embodiments described and illustrated herein may be implemented are shown in FIGS. 13, 14a, 14b, 14c, 15, 16, and 17. FIG. 13 shows system 1300 including a cloud-hosted service 1302 that provides data storage services to various clients 1304, 1306, 1308, 1310, and 1312 via the Internet 1314. In this illustrated example, cloud-hosted service 1302 employs a 3-tier architecture comprising a “front-end” Web server tier including a plurality of Web servers 1316, and application server tier including a plurality of application servers 1318, and a “back-end” or storage tier including a plurality of storage servers and/or storage arrays 1320. The various servers and storage components employed by cloud-hosted service 1302 are coupled in communication via one or more networks and/or fabrics, collectively depicted as network/fabric 1322 for simplicity. Generally, in some implementations or uses, Web servers 1316 may communicate directly with storage servers/arrays 1302, while in other implementations the communication paths between the Web server tier and the storage tier includes application servers 1318.

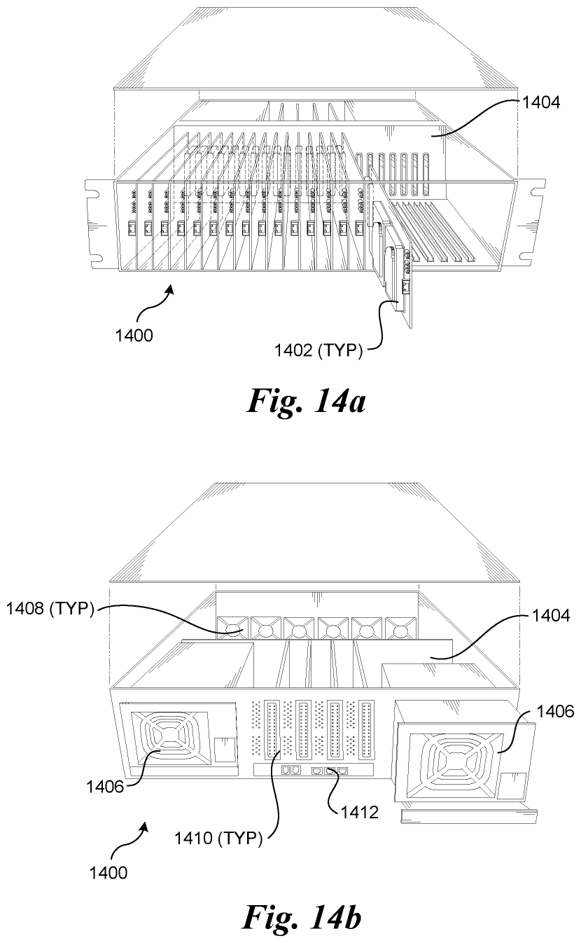

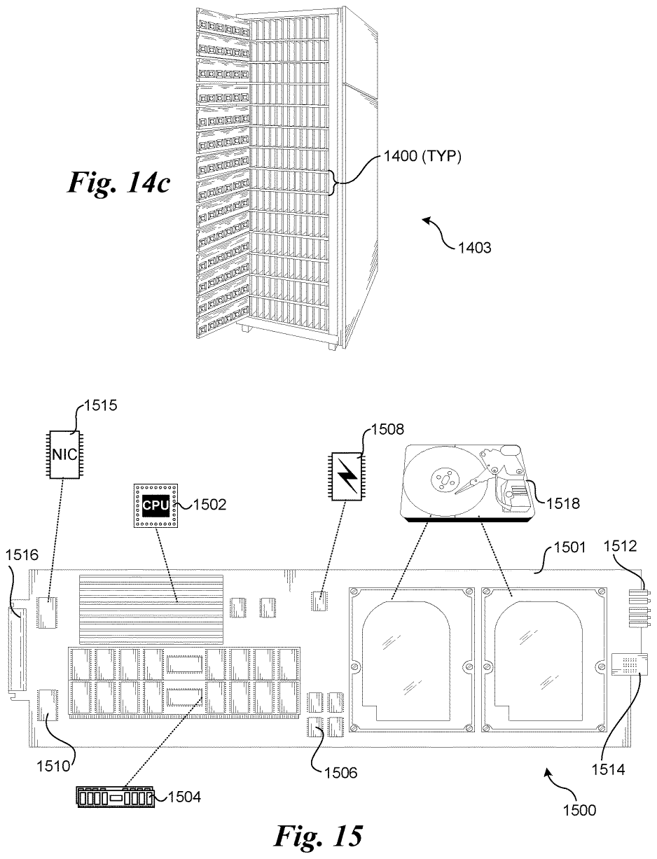

Under some embodiments, the servers and other components depicted in FIG. 13a are installed in a data center or the like. In addition to the components shown, the data center may have other components such as load balancers, and various networking equipment, such as top-of-rack (TOR) switches, as well as management components typically employed in data centers. Details of a blade server architecture that may be used for servers in one or more of the tiers are discussed below with reference to FIGS. 14a-c and 15. Under other embodiments, a cloud-hosted service may lease equipment from companies such as Amazon (Amazon Web Services or AWS), Microsoft (Microsoft Cloud or Microsoft Azure), Google (Google Cloud), and others. Similar cloud services may be implemented using disaggregated architectures employing separate pools of compute, memory, accelerators, storage, etc. So called “serverless” cloud services using distributed microservices may also be implemented

Web servers 1316 are configured to provide communication with clients 1304, 1306, 1308, 1310, and 1312 via Internet 1314. This will usually be facilitated using a conventional networking stack such as HTTP or HTTPS over TCP/IP, under which file transfers may employ a streaming connection or may employ a chunk-based transfer mechanism. In some embodiments, Web servers 1316 will be configured to implement a Web service using a RESTful interface with JSON and/or XML, while other types of Web service interfaces, such as SOAP, may also be used.

As their name implies, application servers 1318 are used to host applications. Under a cloud-hosted storage service, an application may be employed for accessing data that is stored in storage devices in the storage tier. In addition, application servers 1318 may be employed to perform storage replication under which copies of data are stored in data centers at separate geographic locations. Application servers may also include database servers or may support various other types of data architecture schemes. Depending on the required scale, some cloud-hosted services may implement application server functions in the Web servers and/or the storage servers (employing a 2-tier architecture), while other services may employ a 3-tier architecture. 4-tier architectures (not shown) may also be implemented.

The networks and fabrics within a data center are private. They can implement various protocols, including standardized protocols such as TCP/IP, as well as proprietary protocols. Moreover, streaming between tiers within a data center may be implemented with or without HTTP/HTTPS. In addition, since the servers and application software is managed by the cloud-hosted service provider, the software can be configured to support parity-encoded compression decompression for transfers within the data center using pre-determined schemes that do not involve including what parity scheme to use in the headers of the files. At the same time, including the parity information in file headers may also be used.

Communication between Web servers 1316 and clients 1304, 1306, 1308, 1310, and 1312 may use conventional compression/decompression such as conventional DEFLATE or other compression/decompression schemes, with compression match sharing scheme in hardware compression accelerators disclose herein used on the compression side schemes. For example, storage services such as DropBox, Microsoft OneDrive, Google Drive, Box, etc., all include client applications that run on clients to facilitate communication between client devices running the client applications and storage services hosted in one or more data centers. As illustrated, some clients may only support conventional compression and decompression, while other clients may support the fast compression by selecting the positions for comparisons in compression accelerators hardware (as shown in apparatus 900 from FIG. 9.

In view of the foregoing, various implementations of the compression match sharing scheme in hardware compression accelerators may be used, including but not limited to some of the following examples. In important aspect of the embodiments disclosed herein is the compressed files that are generated are formatted in accordance with a compression/decompression standard, such as but no limited to DEFLATE. As a result, conventional decompression software may be used. Accordingly, under an embodiment employing conventional compression/decompression for a client, a file may be stored in a format such as gzip or PKZIP on a storage device in the cloud-hosted server under which the file was created using a compression match sharing scheme in hardware compression accelerators. For transfer of that file within the cloud-hosted service, such as between the storage tier and the application server tier, between the application server tier and the Web server tier, or between the storage tier and the Web server tier, a decompressor configured to implement gzip or PKZIP file may be employed. Meanwhile, file contents that are compressed using the compression match sharing scheme in hardware compression accelerators may be streamed from a Web server 1316 to one of clients 1304, 1306, 1308, 1310, and 1312 and decompressed/decoded without any modification to the conventional gzip or PKZIP (or any other file format implementing conventional DEFLATE) decompressor on the client.

Generally, it is envisioned that aspects of the embodiments herein may be implemented in various types of computing equipment and devices, such as blade servers and other types of servers employed in a data center and/or server farm environment. Typically, the servers used in data centers and server farms comprise arrayed server configurations such as rack-based servers or blade servers. These servers are interconnected in communication via various network provisions, such as partitioning sets of servers into LANs with appropriate switching and routing facilities between the LANs to form a private Intranet. For example, cloud-hosting facilities may typically employ large data centers with a multitude of racks filed with various configurations of servers.

As an overview, exemplary blade server components and systems are shown in FIGS. 14a-c, and 15. Under one configuration, a rack-mounted chassis 1400 is employed to provide power and communication functions for a plurality of server blades (e.g., blades) 1402, each of which occupies a corresponding slot in the chassis. (It is noted that all slots in a chassis do not need to be occupied.) In turn, one or more chassis 1400 may be installed in a blade server rack 1403 shown in FIG. 14c. Each blade is coupled to an interface plane 1404 (e.g., a backplane or mid-plane) upon installation via one or more mating connectors. Generally, the interface plane may include a plurality of respective mating connectors that provide power and communication signals to the blades, and including routed signal paths for coupling network signals or fabric signals between blades. Under current practices, many interface planes provide “hot-swapping” functionality—that is, blades can be added or removed (“hot-swapped”) on the fly, without taking the entire chassis down through appropriate power and data signal buffering.

An exemplary mid-plane interface plane configuration is shown in FIGS. 14a and 14b. The backside of interface plane 1404 is coupled to one or more power supplies 1406. Oftentimes, the power supplies are redundant and hot-swappable, being coupled to appropriate power planes and conditioning circuitry to enable continued operation in the event of a power supply failure. In an optional configuration, an array of power supplies may be used to supply power to an entire rack of blades, wherein there is not a one-to-one power supply-to-chassis correspondence. A plurality of cooling fans 1408 are employed to draw air through the chassis to cool the server blades.

Blade servers generally include the ability to communicate externally with other IT infrastructure, either via communication functionality on the blade server itself or through communication via the midplane or backplane with another card installed in the chassis. For example, this may be facilitated via one or more network connect cards 1410, each of which is coupled to interface plane 1404. Generally, a network connect card may include a physical interface comprising a plurality of network port connections (e.g., RJ-45 ports for wired Ethernet, a SFP or SFP+port for an optical link, a silicon photonics port, etc.), or may comprise a high-density connector designed to directly connect to a network device, such as a network switch, hub, or router. Under disaggregated architectures other types of communication may be provided, such as communication over proprietary fabrics and PCI Express. Systems implementing Open Compute components and architectures may also be used.

Blade servers may provide some type of management interface for managing operations of the individual blades. This may generally be facilitated by a built-in network or communication channel or channels. For example, one or more buses for facilitating a “private” or “management” network and appropriate switching may be built into the interface plane, or a private network may be implemented through closely-coupled network cabling and a network. Optionally, the switching and other management functionality may be provided by a management switch card 1412 that is coupled to the backside or frontside of the interface plane. As yet another option, a management or configuration server may be employed to manage blade activities, wherein communications are handled via standard computer networking infrastructure, for example, Ethernet or an optical network.

With reference to FIG. 15, further details of an exemplary blade 1500 are shown. Each blade comprises a separate computing platform that is configured to perform server-type functions, e.g., is a “server on a card.” Accordingly, each blade includes components common to conventional servers, including a main printed circuit board (main board) 1501 providing internal wiring (e.g., buses) for coupling appropriate integrated circuits (ICs) and other components mounted to the board. These components include one or more processors 1502 coupled to system memory 1504 (e.g., some form of Random Access Memory (RAM)), one or more accelerators 1506 (optional), and a firmware storage device 1508 (e.g., flash memory). A NIC (network interface controller) chip 1510 is provided for supporting conventional network communication functions, such as to support communication between a blade and external network infrastructure. Other illustrated components include status LED (light-emitting diodes) 1512, a set of RJ-45 console ports 1514 (only one of which is shown for simplicity), and a NIC 1515 coupled to an interface plane connector 1516. Additional components include various passive components (e.g., resistors, capacitors), power conditioning components, and peripheral device connectors. Other types of NICs and ports may also be used, such as SPF or SPF+ ports.

Some blades may also provide on-board storage. This is generally facilitated via one or more built-in disk controllers and corresponding connectors to which one or more disk drives 1518 are coupled. For example, common disk controllers include SATA controllers, SCSI controllers, and the like. Other types of disk controllers may also be used. Additionally, solid state drive (SSD) may be used in place of disk drive 1518. As an option, the disk drives may be housed separate from the blades in the same or a separate rack, such as might be the case when a network-attached storage (NAS) appliance or backend storage sub-system that is employed for storing large volumes of data. Under a disaggregated architecture storage devices may be installed in pooled storage drawers that are separate from pooled compute drawers in which server blades or server modules are installed.

In addition to the illustrated components, a blade or other type of compute platform may include one or more accelerators that may be used to implement the compression match sharing scheme in hardware compression accelerators. For example, accelerators may be included in a processor SoC (System on a Chip) or SoP (System on Package) and/or may be implemented in a separate discrete component.

Generally, a client device may include any type of computing device or system that is configured to communicate over a network and run suitable compression/decompression software. Such computing devices include but are not limited to laptops, notebooks, desktop computers, workstations, mobile phones, tablets, etc.

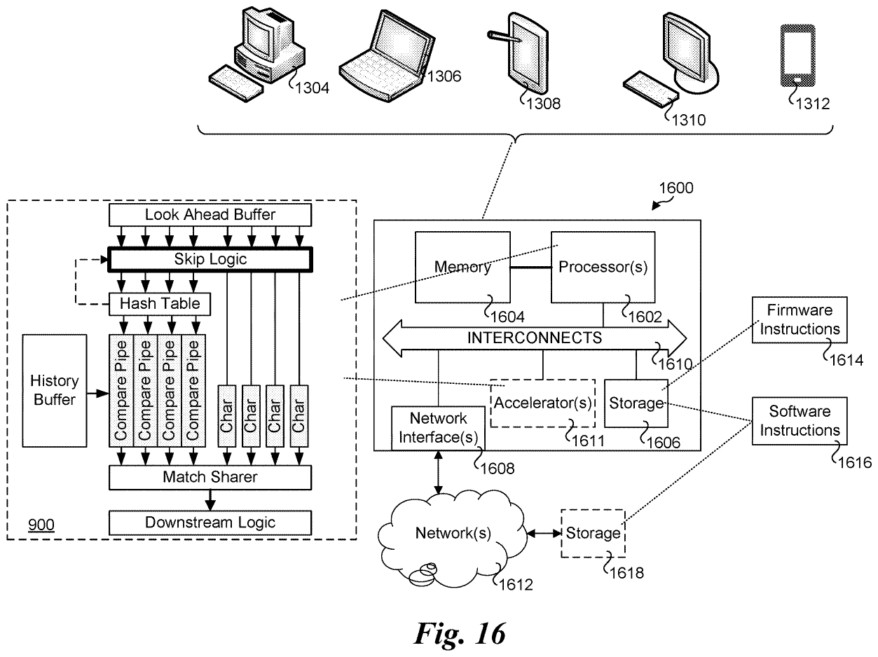

FIG. 16 shows an abstracted platform architecture 1600 including some basic components found in each of clients 1304 (desktop computer/workstation), 1306 (laptop or notebook), 1308 (tablet), 1310 (all-in-one computer, such as an iMac), and 1312 (mobile phone). As illustrated, each of these computing device/systems includes one or more processors 1602, memory 1604, one or more storage devices 1606, and one or more network interfaces 1608. These components, as well as other components that are not shown are interconnected via various interconnect circuitry, which is depicted as interconnects 1610 for simplicity.

Generally, processor(s) 1602 may include a single-core or multi-core processor having various types of architecture. Some processors may employ an SoC or SoP architecture including various built-in interfaces and supporting various functions, including accelerators used for compression/decompression. A processor may include an integrated Graphics Processing Unit (GPU), or the platform hardware may include a GPU that is separate from the processor (as well as no GPU). Optionally, one or more discrete devices may be used to implement accelerator(s) 1611.

Network interface(s) may include one or more of wired and wireless interfaces that support communication over one or more networks 1612. For example, desktops, laptops, notebooks, and all-in-one computers may include Ethernet interfaces or adaptors, as well as an IEEE 802.11-based wireless (Wi-Fi) interface. Tablets and mobile phones may include mobile radios to support communication over mobile networks, as well as Wi-Fi interfaces.

Platform firmware instructions 1614 will generally be stored in some form of non-volatile storage device 1606, such as a Flash memory device, while software instructions 1616 may be stored in an on-board storage device and/or may be stored somewhere on a network storage device 1618 and loaded over a network. For example, software instructions, including an operating system may be stored on in a disk drive (magnetic or SSD) for desktops, laptops, notebooks, and all-in-one computers, while operating system and application software will be stored in Flash memory or the like for mobile phones and tables. The software instructions may be loaded from storage into memory 1604 and executed on the one or more processors 1602 to effect various operations, including the compression and decompression schemes described and illustrated herein. Generally, software instructions may be directly executed on a processor or executed on a virtual machine that is hosted by the computing device or system.

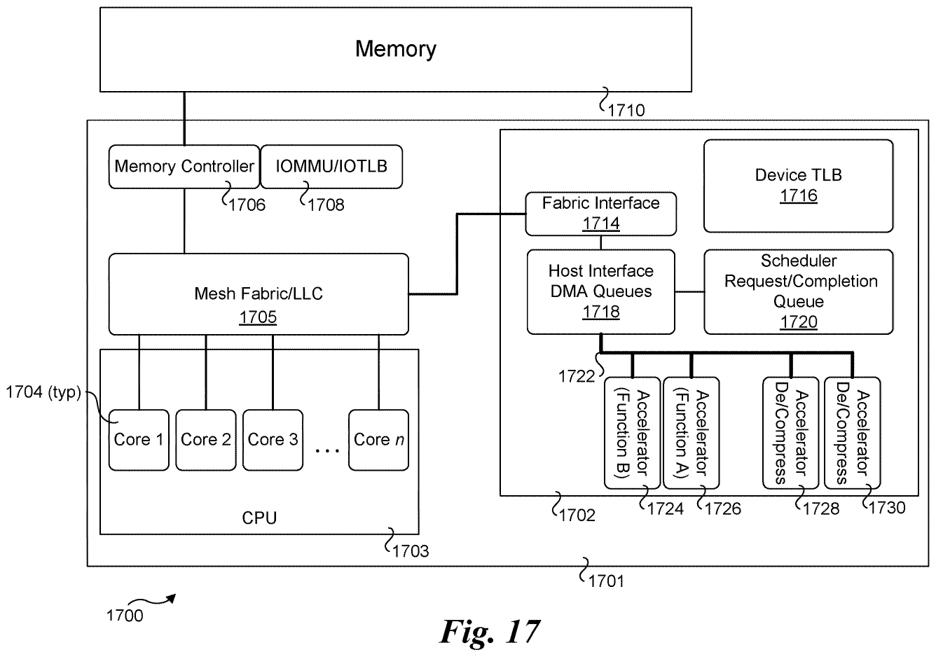

FIG. 17 shows a platform architecture 1700 including a processor 1701 having an on-chip accelerator 1702 (also referred to as an accelerator complex when the accelerator supports multiple instances of accelerator functions). Processor 1701 includes a Central Processing Unit (CPU) 1703 including n cores 1704, each with a private L1 and L2 cache (not shown). Each of cores 1704 is connected to a mesh fabric/LLC (last-level cache) block 1705, which is coupled to a memory controller 1706 with an associated Input-Output Memory Management Unit and Input-Output Translation Lookaside Buffer (IOMMU/IOTLB) 1708. Memory controller 1706 is coupled to memory 1710, which is illustrative of one or more DRAM memory devices, such as DDR5 DIMMS. Memory 1710 may also be implemented using one or more Non-Volatile DIMMs (NVDIMMs). Generally, Memory controller 1706 would be coupled to the DRAM memory devices with one or more memory channels per DRAM memory device (not shown).

FIG. 17 further shows an embodiment of an on-chip accelerator 1712, which is representative of various types of accelerators. On-chip accelerator 1712 includes a fabric interface 1714, a device TLB 1716, host interface DMA queues 1718, a scheduler request/completion queue 1720, and a bus 1722 to which multiple accelerators are coupled as depicted by accelerators 1724, 1726, 1728, and 1730. Fabric interface 1714 is generally illustrative of various types of IO interfaces that can connect an on-chip accelerator to the interconnect infrastructure on the processor/SoC, as collectively illustrated and described herein as a mesh fabric. The interconnect structure and protocol may generally include both proprietary and standards-based interconnects.

Accelerators are generally used to off-load CPU intensive tasks from a processor's cores, such as compression and decompression functions, which are math-intensive. In the embodiments herein, some or all of the accelerators may be further configured to generate a decryption key and used the decryption key for performing decryption and (optional) encryption operations. For illustrative purposes, accelerators 1724 and 1726 are depicted as being configured to perform the respective functions A and B, such as but not limited to encryption and decryption. Meanwhile, accelerators 1728 and 1730 are depicted as performing compression and/or decompression operations with parity encoding in accordance with one or more embodiments described herein.

Generally, an accelerator may include embedded circuitry and logic that is tailored to efficiently perform one or more specialized tasks, such as the parity-encoded compression and decompression functions described and illustrated herein. The circuitry may be in the form of an ASIC (application-specific integrated circuit), or may include programmable circuitry/logic, such as provided via an FPGA. Such an FPGA may comprise one or more FPGA blocks, such as are available via license from various manufacturers. An FPGA block may also incorporate a custom design. Generally, the ASIC, FPGA block, or similar embedded circuitry and logic is referred to herein as a functional unit, which is designed to perform a corresponding function. A given accelerator may include one or more functional units.

More generally, an accelerator may also be referred to as an “engine,” wherein the engine may be programmed to perform one or more dedicated functions. In some embodiments, an engine may operate in a similar manner to an embedded processor, and be enabled to execute instructions (e.g., accelerator application/function instructions) for dedicated functions. An engine may also combine both execution of instructions in combination with embedded circuitry and logic.

Accelerators have steadily improved in capability with one of the most significant recent trends being “shared virtual memory” (SVM)-capable accelerators. The traditional accelerator needed to be managed as an IO device in its own personal address space; this was accomplished with expensive kernel-mode drivers (KMD) that needed applications to cross back and forth between user and kernel-space, pinning pages in memory or copying user buffers to/from special buffers managed by the OS/Kernel-mode-driver. With SVM, the accelerator or IO device can directly work on the address space of user application thread running on a CPU, as it shares the same virtual->physical address translation capabilities as the user application thread. This is a key improvement in accelerator efficiency (from the point of view of data movement), enables user-mode submissions directly to the accelerators (via a “user-mode-driver” or UMD) and results in easier programming models and adoption. In one embodiment, platform architecture 1700 is configured to implement SVM-capable accelerators.

In another embodiment, the circuitry, logic, and components for implementing the match sharing schemes are implemented in a memory controller. Under this approach the memory controller may receive a byte stream to write to memory and compress the byte stream prior to writing data in the compressed byte stream to the memory.

Generally, the teachings and principles disclosed in the embodiments herein may be implemented for any application employing compression of data, such as but not limited to data files and byte streams. The hardware-based compression solutions disclosed herein provide improvement over existing schemes including compressing data at faster rates and greater compression levels.

While various embodiments described herein use the term System-on-a-Chip or System-on-Chip (“SoC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

In addition to embedding the circuitry, logic, and components in the embodiments herein in CPUs, SoCs, and SoPs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU in the illustrated embodiments. Moreover, as used in the following claims, the term “processor” is used to generically cover CPUs and various forms of XPUs.

The following examples pertain to additional examples of the teachings and principles disclosed herein.

Example 1. A method for processing a byte stream, comprising implementing M compare pipelines configured to perform compare operations used to identify instances of string matches in the byte stream. For a sequence of N positions in a lookahead buffer, selecting M out of the N positions for which compare operations are to be performed using the M compare pipelines, where M<N, and for the N positions not being among the M positions, forwarding a character at that position for further processing.

Example 2. The method of example 1, wherein selecting the M out of the N positions for which compare operations are to be performed utilizes a permutation order comprising a permutation of an original order of the sequence of N positions.

Example 3. The method of example 2, wherein selecting the M out of the N positions for which compare operations are to be performed further comprises for each of the N positions, selecting a search string comprising a sequence of characters at sequential positions in the lookahead buffer, each of the search strings having a common length, generating a respective hash of the search string for each of the N positions, and detecting if there are any hash collisions.

Example 4. The method of example 3, further comprising, when there are no hash collisions, using the first M positions in the permutation order; otherwise, for a hash collision, skipping a position with an earlier position in the permutation order until a number of unskipped positions in the permutation order equals M.

Example 5. The method of example 3 or 4, further comprising implementing a hash table in j memory banks, and searching the hash table for a hash using a number of least significant bits in the hash to identify a memory bank among the j memory banks to search.

Example 6. The method of any of examples 2-5, further comprising using alternating permutation orders to select the M out of the N positions for successive sequences of N positions in the lookahead buffer.

Example 7. The method of any of the preceding examples, further comprising, for one of the M positions comprising a current position, selecting a search string comprising a sequence of characters at sequential positions in the lookahead buffer beginning at the current position, and obtaining a forward match location of an instance of the sequence of characters matching the search string in a history buffer.

Example 8. The method of example 7, further comprising, for the forward match location and the current position, generating a compare result identifying a location in the history buffer of a longest match length of a string in the history buffer including the instance of the search string at the forward match location and matching a string of characters in the lookahead buffer including the search string.

Example 9. An apparatus, comprising a lookahead buffer configured to buffer a first portion of a remainder of a byte stream, skip logic comprising circuitry and logic configured, for a sequence of N positions in the lookahead buffer, to select M out of the N positions for which compare operations are to be performed, where M<N and a hash table. The apparatus further includes a history buffer configured to buffer a second portion of the byte stream that may or may not include the first portion of the remainder of the byte stream, and a plurality of compare pipelines, configured to perform the compare operations, wherein the apparatus is configured to perform compare operations for the M positions that are selected in parallel.

Example 10. The apparatus of example 9, wherein the skip logic is configured to select the M out of the N positions for which compare operations are to be performed using a permutation order comprising a permutation of an original order of the sequence of N positions.

Example 11. The apparatus of example 10, wherein the skip logic is further configured to selecting the M out of the N positions for which compare operations are to be performed further comprises, for each of the N positions, select a search string comprising a sequence of characters at sequential positions in the lookahead buffer, each of the search strings having a common length, generate a respective hash of the search string for each of the N positions, and detect if there are any hash collisions.

Example 12. The apparatus of example 11, further configured to:
when there are no hash collisions, use the first M positions in the permutation order; otherwise, for a hash collision, skipping a position with an earlier position in the permutation order until a number of unskipped positions in the permutation order equals M.

Example 13. The apparatus of example 11 or 12, further configured to implement a hash table in j memory banks, and search the hash table for a hash using a number of least significant bits in the hash to identify a memory bank among the j memory banks to search.

Example 14. The apparatus of any of examples 10-13, wherein the skip logic is configured to use alternating permutation orders to select the M out of the N positions for successive sequences of N positions in the lookahead buffer.

Example 15. The apparatus of any of examples 9-14, further comprising circuitry and logic to, for one of the M positions comprising a current position, select a search string comprising a sequence of characters at sequential positions in the lookahead buffer beginning at the current position, and obtain a forward match location of an instance of the sequence of characters matching the search string in a history buffer.

Example 16. The apparatus of example 15, further comprising circuitry and logic to, for the forward match location and the current position, generate a compare result identifying a location in the history buffer of a longest match length of a string in the history buffer including the instance of the search string at the forward match location and matching a string of characters in the lookahead buffer including the search string.

Example 17. An apparatus comprising a lookahead buffer configured to buffer a first portion of a byte stream, a skip logic comprising circuitry and logic configured, for a sequence of N positions in the lookahead buffer, to select M out of the N positions for which compare operations are to be performed, where M<N, and a hash table. The apparatus further includes a history buffer configured to buffer a second portion of the byte stream that may or may not include the first portion of the byte stream, a plurality of compare pipelines, configured to perform the compare operations, and a match sharer including circuitry and logic to implement adjacency-based match sharing, wherein the apparatus is configured to perform compare operations for the M positions that are selected in parallel and provide outputs of the compare operations as inputs to the match sharer.

Example 18. The apparatus of example 17, wherein the apparatus is further configured to, for each of the N positions that are not among the M positions, provide a character at the position to the match sharer.

Example 19. The apparatus of example 17 or 18, wherein the match sharer includes a sequence of entries arranged in a pipeline, and wherein the match sharer is configured to sort compare results it receives from the compare pipelines and share the sorted compare results with logic blocks in the match sharer pipeline.

Example 20. The apparatus of example 19, further comprising downstream logic coupled to an output of the match sharer, wherein for each of multiple compare cycles for respective positions in the byte stream the match sharer outputs a best match entry at the last position in the match sharer pipeline, and wherein the downstream logic processes the best match entries to generate an encoded compressed byte stream.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Capital letters, such as ‘M’ and ‘N’ and italicized letters such as ‘n’, in the foregoing detailed description are used to depict an integer number, and the use of a particular letter is not limited to particular embodiments. Moreover, the same letter may be used in separate claims to represent separate integer numbers, or different letters may be used. In addition, use of a particular letter in the detailed description may or may not match the letter used in a claim that pertains to the same subject matter in the detailed description.

As discussed above, various aspects of the embodiments herein may be facilitated by corresponding firmware components such as firmware executed by an embedded processor or the like. Thus, embodiments may be used as or to support firmware executed upon some form of processor, processing core, or embedded logic, or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (i.e., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments, including what is described in the Abstract, is not intended to be exhaustive or to limit the embodiments to the precise forms disclosed. While specific embodiments of, and examples for, the teachings and principles are described herein for illustrative purposes, various equivalent modifications are possible within the scope of the claims, as those skilled in the relevant art will recognize.

These modifications can be made to the embodiments in light of the above detailed description. The terms used in the following claims should not be construed to limit the claim scope to the specific embodiments disclosed in the specification and the drawings. Rather, the scope of the claims is to be determined entirely by the following claims, which are to be construed in accordance with established doctrines of claim interpretation.

What is claimed is:

1. A method for processing a byte stream, comprising:
implementing M compare pipelines configured to perform compare operations used to identify instances of string matches in the byte stream;
for a sequence of N positions in a lookahead buffer, selecting M out of the N positions for which compare operations are to be performed using the M compare pipelines, where M<N; and
for the N positions not being among the M positions, forwarding a character at that position for further processing.

2. The method of claim 1, wherein selecting the M out of the N positions for which compare operations are to be performed utilizes a permutation order comprising a permutation of an original order of the sequence of N positions.

3. The method of claim 2, further comprising using alternating permutation orders to select the M out of the N positions for successive sequences of N positions in the lookahead buffer.

4. The method of claim 2, wherein selecting the M out of the N positions for which compare operations are to be performed further comprises:
for each of the N positions, selecting a search string comprising a sequence of characters at sequential positions in the lookahead buffer, each of the search strings having a common length;
generating a respective hash of the search string for each of the N positions; and
detecting if there are any hash collisions.

5. The method of claim 4, further comprising:
when there are no hash collisions, using the first M positions in the permutation order; otherwise,
for a hash collision, skipping a position with an earlier position in the permutation order until a number of unskipped positions in the permutation order equals M.

6. The method of claim 4, further comprising:
implementing a hash table in j memory banks; and
searching the hash table for a hash using a number of least significant bits in the hash to identify a memory bank among the j memory banks to search.

7. The method of claim 1, further comprising:
for one of the M positions comprising a current position;
selecting a search string comprising a sequence of characters at sequential positions in the lookahead buffer beginning at the current position; and
obtaining a forward match location of an instance of the sequence of characters matching the search string in a history buffer.

8. The method of claim 7, further comprising:
for the forward match location and the current position,
generating a compare result identifying a location in the history buffer of a longest match length of a string in the history buffer including the instance of the search string at the forward match location and matching a string of characters in the lookahead buffer including the search string.

9. An apparatus, comprising:
a lookahead buffer configured to buffer a first portion of a remainder of a byte stream;
skip logic comprising circuitry and logic configured, for a sequence of N positions in the lookahead buffer, to select M out of the N positions for which compare operations are to be performed, where M<N;
a hash table;
a history buffer configured to buffer a second portion of the byte stream that may or may not include the first portion of the remainder of the byte stream; and
a plurality of compare pipelines, configured to perform the compare operations,
wherein the apparatus is configured to perform compare operations for the M positions that are selected in parallel.

10. The apparatus of claim 9, wherein the skip logic is configured to select the M out of the N positions for which compare operations are to be performed using a permutation order comprising a permutation of an original order of the sequence of N positions.

11. The apparatus of claim 10, wherein the skip logic is further configured to selecting the M out of the N positions for which compare operations are to be performed further comprises:
for each of the N positions, select a search string comprising a sequence of characters at sequential positions in the lookahead buffer, each of the search strings having a common length;
generate a respective hash of the search string for each of the N positions; and
detect if there are any hash collisions.

12. The apparatus of claim 11, further configured to:
when there are no hash collisions, use the first M positions in the permutation order; otherwise,
for a hash collision, skipping a position with an earlier position in the permutation order until a number of unskipped positions in the permutation order equals M.

13. The apparatus of claim 11, further configured to:
implement a hash table in j memory banks; and
search the hash table for a hash using a number of least significant bits in the hash to identify a memory bank among the j memory banks to search.

14. The apparatus of claim 10, wherein the skip logic is configured to use alternating permutation orders to select the M out of the N positions for successive sequences of N positions in the lookahead buffer.

15. The apparatus of claim 9, further comprising circuitry and logic to:
for one of the M positions comprising a current position;
select a search string comprising a sequence of characters at sequential positions in the lookahead buffer beginning at the current position;
obtain a forward match location of an instance of the sequence of characters matching the search string in a history buffer.

16. The apparatus of claim 15, further comprising circuitry and logic to:
for the forward match location and the current position,
generate a compare result identifying a location in the history buffer of a longest match length of a string in the history buffer including the instance of the search string at the forward match location and matching a string of characters in the lookahead buffer including the search string.

17. An apparatus comprising:
a lookahead buffer configured to buffer a first portion of a byte stream;
a skip logic comprising circuitry and logic configured, for a sequence of N positions in the lookahead buffer, to select M out of the N positions for which compare operations are to be performed, where M<N;
a hash table;
a history buffer configured to buffer a second portion of the byte stream that may or may not include the first portion of the byte stream; and
a plurality of compare pipelines, configured to perform the compare operations; and
a match sharer including circuitry and logic to implement adjacency-based match sharing;
wherein the apparatus is configured to perform compare operations for the M positions that are selected in parallel and provide outputs of the compare operations as inputs to the match sharer.

18. The apparatus of claim 17, wherein the apparatus is further configured to:
for each of the N positions that are not among the M positions, provide a character at the position to the match sharer.

19. The apparatus of claim 17, wherein the match sharer includes a sequence of entries arranged in a pipeline, and wherein the match sharer is configured to sort compare results it receives from the compare pipelines and share the sorted compare results with logic blocks in the match sharer pipeline.

20. The apparatus of claim 19, further comprising downstream logic coupled to an output of the match sharer, wherein for each of multiple compare cycles for respective positions in the byte stream the match sharer outputs a best match entry at the last position in the match sharer pipeline, and wherein the downstream logic processes the best match entries to generate an encoded compressed byte stream.
